(19) United States
(12) Patent Application Publication
(10) Pub. No.: US 2026/0037706 A1
(43) Pub. Date: Feb. 5, 2026

(54) AUTOMATED SIGNAL ELECTROMIGRATION VIOLATION RESOLUTION FOR LOGIC CIRCUIT DESIGNS

(71) Applicant: INTERNATIONAL BUSINESS MACHINES CORPORATION, Armonk, NY (US)

(72) Inventors: Jeffrey HEMMETT, St. George, VT (US); Vasant RAO, Fishkill, NY (US); XIN ZHAO, Hopewell Junction, NY (US); Ravi Chander LEDALLA, Fishkill, NY (US)

(21) Appl. No.: 18/791,563

(22) Filed: Aug. 1, 2024

(51) Int. Cl. G06F 30/3308; G06F 30/323

(52) U.S. Cl. CPC G06F 30/3308; G06F 30/323

(57) ABSTRACT

An automated signal electromigration violation resolution process is provided for a logic circuit design of an integrated circuit. The automated resolution process includes simulating, by at least one processor set, signal electromigration (SEM) for a logic circuit design of an integrated circuit, where the simulating generates signal electromigration metrics for the logic circuit design. Further, the process includes automatedly resolving, based on evaluating the signal electromigration metrics for violations, a signal electromigration metric violation of the logic circuit design. The automatedly resolving includes generating a signal electromigration limit-to-metric ratio for the metric violation, and auto-adjusting, using the generated limit-to-metric ratio, a switching factor of the logic circuit design to facilitate resolving the signal electromigration violation. Further, the process includes reevaluating the signal electromigration metrics of the logic circuit design using the auto-adjusted switching factor to confirm automated resolution of the signal electromigration metric violation.

### BACKGROUND

The present invention relates to the design and manufacture of integrated circuits (ICs), and specifically, to very large-scale integration (VLSI) designs and devices based on the analysis and optimization of such circuits.

Signal electromigration (SEM) analysis is one type of analysis of a logic circuit design to facilitate improving or optimizing the circuit design. Electromigration is a type of potential fault mechanism in integrated circuits, caused by the movement of atoms based on the flow of current through material. Electromigration can result in both vacancies and deposits within, for instance, a wire or gate of the integrated circuit. As part of the design and fabrication of integrated circuits, simulation of electromigration can be performed in modern technology computer aided design (TCAD) tools.

### SUMMARY

Certain shortcomings of the prior art are overcome, and additional advantages are provided herein through the provision of a computer-implemented method of facilitating circuit design processing within a computer environment. The computer-implemented method includes simulating, by at least one processor set, signal electromigration (SEM) for a logic circuit design of an integrated circuit, where the simulating generates signal electromigration metrics for the logic circuit design. Further, the computer-implemented method includes automatedly resolving. based on evaluating the signal electromigration metrics for violations, a signal electromigration metric violation of the logic circuit design. The automatedly resolving includes generating a signal electromigration limit-to-metric ratio for the signal electromigration metric violation of the logic circuit design, and auto-adjusting, using the generated signal electromigration limit-to-metric ratio, a switching factor of the logic circuit design to facilitate resolving the signal electromigration metric violation of the logic circuit design. Further, the computer-implemented method includes reevaluating the signal electromigration metrics of the logic circuit design using the auto-adjusted switching factor to confirm automated resolution of the signal electromigration metric violation.

Computer program products and computer systems relating to one or more aspects are also claimed herein. Further, services relating to one or more aspects are also described and may be claimed herein.

Additional features and advantages are realized through the techniques described herein. Other embodiments and aspects are described in detail herein and are considered part of the claimed aspects.

### BRIEF DESCRIPTION OF THE DRAWINGS

One or more aspects are particularly pointed out and distinctly claimed as examples in the claims at the conclusion of the specification. The foregoing and objects, features, and advantages of one or more aspects are apparent from the following detailed description taken in conjunction with the accompanying drawings in which:

FIG. 1 depicts one example of a computing environment to include and/or use one or more of the aspects of the present disclosure;

FIG. 2A depicts one embodiment of a computer program product with a signal electromigration analysis and circuit design module, in accordance with one or more aspects of the present disclosure;

FIG. 2B depicts one embodiment of a perform signal electromigration analysis sub-module, in accordance with one or more aspects of the present disclosure;

FIG. 2C depicts one embodiment of a defined transition sub-matrices sub-module of a perform signal electromigration analysis sub-module such as depicted in FIG. 2B, in accordance with one or more aspects of the present disclosure;

FIG. 3A depicts one embodiment of a signal electromigration analysis and circuit design process, in accordance with one or more aspects of the present disclosure;

FIG. 3B depicts one embodiment of a perform signal electromigration analysis on a logic circuit design process, in accordance with one or more aspects of the present disclosure;

FIG. 4 illustrates an exemplary logic gate and related timing graph model;

FIG. 5 illustrates another exemplary logic circuit and an associated channel connected components (CCC) timing graph model built using transistor-level static timing;

FIG. 6A depicts another embodiment of a logic circuit design and associated channel connected components (CCC) timing graph model;

FIG. 6B is an exemplary state-analysis-based transition matrix containing transitions within a channel connected components expression of the logic circuit design of FIG. 6A, in accordance with one or more aspects of the present disclosure;

FIG. 7 depicts one embodiment of signal electromigration weight factor determination, in accordance with one or more aspects of the present disclosure;

FIG. 8 depicts one embodiment of a full timing model signal electromigration weight analysis workflow, in accordance with one or more aspects of the present disclosure;

FIG. 9A-9B depict exemplary transition submatrices per output of a logic circuit design obtained by partitioning the full state-analysis-based transition matrix, in accordance with one or more aspects of the present disclosure;

FIG. 10 depicts one embodiment of a per output signal electromigration weight factor workflow, in accordance with one or more aspects of the present disclosure;

FIG. 11A is another exemplary logic gate of a logic circuit design, in accordance with one or more aspects of the present disclosure;

FIGS. 11B-11C depict exemplary per timing arc transition submatrices (or per propagate segment (pseg)) obtained by partitioning the state-analysis-based transition matrix for the logic circuit design of FIG. 11A per timing arc, in accordance with one or more aspects of the present disclosure;

FIG. 12 depicts one embodiment of a per pseg signal electromigration weighting factor workflow, in accordance with one or more aspects of the present disclosure;

FIG. 13 depicts one embodiment of a hybrid signal electromigration workflow, in accordance with one or more aspects of the present disclosure;

FIG. 14 depicts one embodiment of an automated signal electromigration violation resolution workflow, in accordance with one or more aspects of the present disclosure;

FIG. 15 is a flow diagram of a design process used in semiconductor design, manufacture, and test, in accordance with one or more aspects of the present disclosure;

FIG. 16 depicts a further example of integrated circuit fabrication, including generating physical design data, in accordance with one or more aspects of the present disclosure; and

FIG. 17 shows an exemplary high-level Electronic Design Automation (EDA) tool flow, in which aspects of present disclosure can be employed.

### DETAILED DESCRIPTION

Aspects of the present disclosure and certain features, advantages, and details thereof, are explained more fully below with reference to the non-limiting example(s) illustrated in the accompanying drawings. Descriptions of well-known systems, devices, processing techniques, etc., are omitted so as not to unnecessarily obscure the disclosure in detail. It should be understood, however, that the detailed description and the specific example(s), while indicating aspects of the disclosure, are given by way of illustration only, and are not by way of limitation.

Various substitutions, modifications, additions, and/or arrangements, within the spirit and/or scope of the underlying inventive concepts will be apparent to those skilled in the art for this disclosure. Note further that reference is made below to the drawings, where the same or similar reference numbers used throughout different figures designate the same or similar components. Also, note that numerous inventive aspects and features are disclosed herein, and unless otherwise inconsistent, each disclosed aspect or feature is combinable with any other disclosed aspect or feature as desired for a particular application of the concepts disclosed.

Note also that illustrative embodiments are described below using specific code, designs, architectures, protocols, layouts, schematics, systems, or tools only as examples, and not by way of limitation. Furthermore, the illustrative embodiments are described in certain instances using particular software, hardware, tools, and/or data processing environments only as example for clarity of description. The illustrative embodiments can be used in conjunction with other comparable or similarly purposed structures, systems, applications, architectures, etc. One or more aspects of an illustrative control embodiment can be implemented in software, hardware, or a combination thereof.

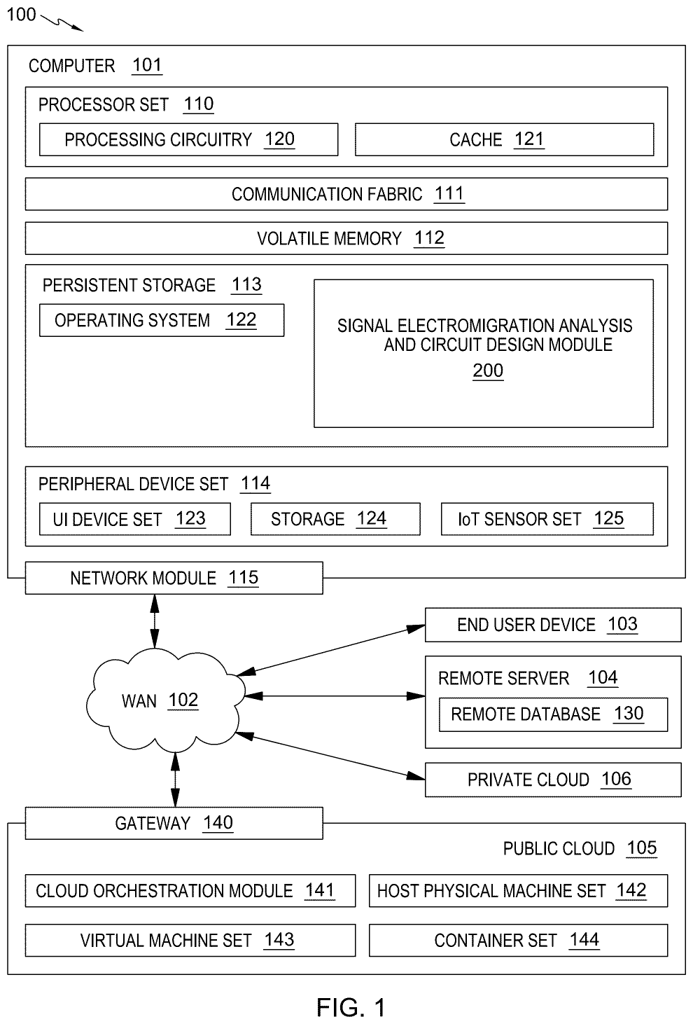

As understood by one skilled in the art, program code, as referred to in this application, can include software and/or hardware. For example, program code in certain embodiments of the present disclosure can utilize a software-based implementation of the functions described, while other embodiments can include fixed function hardware. Certain embodiments combine both types of program code. Examples of program code, also referred to as one or more programs, are depicted in FIG. 1, including operating system 122 and signal electromigration analysis and circuit design module 200, which are stored in persistent storage 113.

One or more aspects of the present disclosure are incorporated in, performed and/or used by a computing environment. As examples, the computing environment can be of various architectures and of various types, including, but not limited to: personal computing, client-server, distributed, virtual, emulated, partitioned, non-partitioned, cloud-based, quantum, grid, time-sharing, clustered, peer-to-peer, mobile, having one node or multiple nodes, having one or more processor sets, each with one processor or multiple processors, and/or any other type of environment and/or configuration, etc., that is capable of executing a process (or multiple processes) that, e.g., perform capacitance extraction-related processing, such as disclosed herein. Aspects of the present disclosure are not limited to a particular architecture or environment.

Prior to further describing detailed embodiments of the present disclosure, an example of a computing environment to include and/or use one or more aspects of the present disclosure is discussed below with reference to FIG. 1.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as signal electromigration analysis and circuit design module or block 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Cloud computing services and/or microservices (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to an “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

The computing environment described above is only one example of a computing environment to incorporate, perform and/or use one or more aspects of the present disclosure. Other examples are possible. Further, in one or more embodiments, one or more of the components/modules of FIG. 1 need not be included in the computing environment and/or are not used for one or more aspects of the present disclosure. Further, in one or more embodiments, additional and/or other components/modules can be used. Other variations are possible.

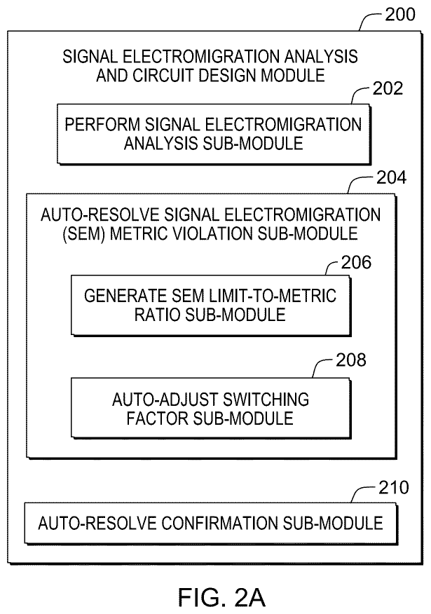

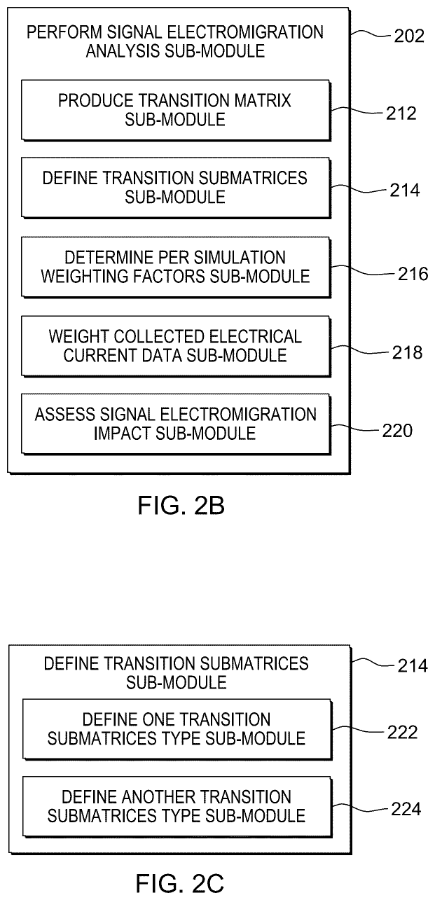

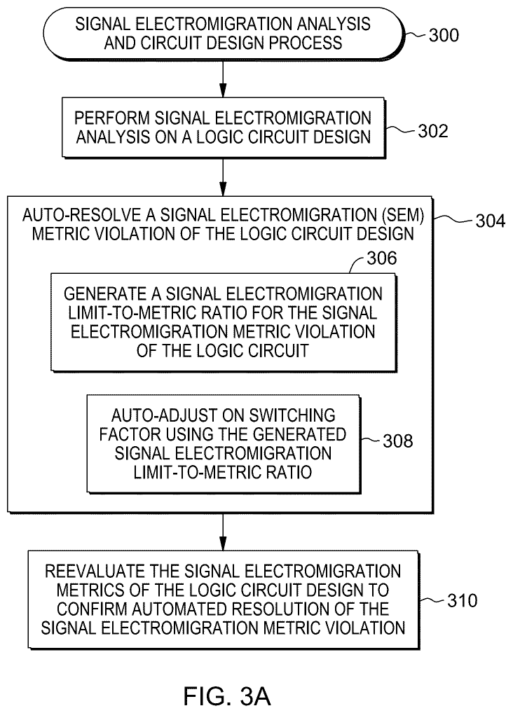

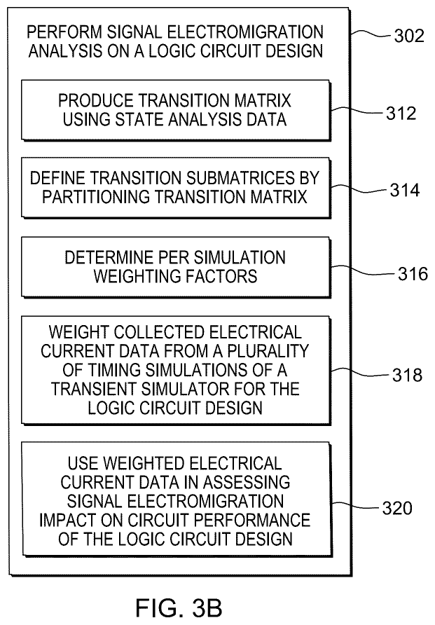

By way of example, one or more embodiments of a signal electromigration analysis and circuit design module and process are described initially with reference to FIGS. 2A-3B. FIGS. 2A-2C depict one embodiment of a signal electromigration analysis and circuit design module 200 that includes code or instructions to perform signal electromigration analysis and automated violation resolution processing, in accordance with one or more aspects of the present disclosure, and FIGS. 3A-3B depict one embodiment of a signal electromigration analysis and circuit design process, in accordance with one or more aspects of the present disclosure.

Referring to FIGS. 1-2C, signal electromigration analysis and circuit design module 200 includes, in one example, various sub-modules used to perform processing, in accordance with one or more aspects of the present disclosure. The sub-modules are, e.g., computer-readable program code (e.g., instructions) in computer-readable media (e.g., persistent storage (e.g., persistent storage 113, such as a disk) and/or a cache (e.g., cache 121), as examples). The computer-readable media can be part of a computer program product and can be executed by and/or using one or more computers, such as computer(s) 101; one or more processor sets 110 (FIG. 1); processors, such as one or more processors of processor set 110; and/or processing circuitry, such as processing circuitry of processor set 110, etc.

As noted, FIG. 2A depicts one embodiment of signal electromigration analysis and circuit design module 200 which, in one or more implementations, includes, or facilitates, automated signal electromigration violation resolution processing in accordance with one or more aspects of the present disclosure. In the embodiment of FIG. 2A, example sub-modules of signal electromigration analysis and circuit design module 200 include a perform signal electromigration analysis sub-module 202 to facilitate performing signal electromigration analysis on a logic circuit design for an integrated circuit. In one or more embodiments, performing signal electromigration analysis sub-module 202 implements an automated process for evaluating signal electromigration metrics (e.g., electrical current data) generated from simulating, by at least one processor set, signal electromigration for a logic circuit design of an integrated circuit. One example of the perform signal electromigration analysis sub-module 202 is described further below with reference to FIGS. 2B-2C, by way of example only.

In one or more embodiments, signal electromigration analysis and circuit design module 200 also includes an auto-resolve signal electromigration metric violation sub-module 204, which in one embodiment, includes a generate signal electromigration (SEM) limit-to-metric ratio sub-module 206 to generate a signal electromigration limit-to-metric ratio based on the signal electromigration metric violation of the integrated circuit design, and an auto-adjust switching factor sub-module 208 to auto-adjust, using the generated signal electromigration limit-to-metric ratio, a switching factor for the logic circuit design to facilitate automatic resolving of the signal electromigration metric violation of the logic circuit design. Further, in one or more embodiments, the signal electromigration analysis and circuit design module 200 includes an auto-resolve confirmation sub-module 210 which reevaluates the signal electromigration metrics of the logic circuit design using the auto-adjusted switching factor to confirm automated resolution of the signal electromigration metric violation.

As described herein, in one or more embodiments, signal electromigration analysis and circuit design module 200 can further include a facilitate generation of modified logic circuit design sub-module (not shown), which, based on the results of reevaluating the signal electromigration metrics of the logic circuit design using the auto-adjusted switching factor, can identify a real signal electromigration violation for the logic circuit design and initiate generating a modified logic circuit design through, for instance, modifying of the logic circuit design to remediate one or more identified real signal electromigration issues with the logic circuit design. For instance, in one or more embodiment, a real signal electromigration violation can be identified where the signal electromigration analysis identifies an issue with the metrics, such as a singularity, or where the switching factor auto-adjustment results in the adjusted switching factor being below a minimum set switching factor limit for the logic circuit design.

Note that although various sub-modules are described herein, signal electromigration analysis and circuit design processing, such as disclosed, can use, or include, additional, fewer, and/or different sub-modules. A particular sub-module can include additional code, including code of other sub-modules, or less code. Further, additional and/or fewer sub-modules can be used. Many variations are possible.

By way of example, FIGS. 2B-2C depict one embodiment of performing signal electromigration analysis sub-module 202, which can be used in association with signal electromigration analysis and circuit design module 200 of FIG. 2A. As shown, in one embodiment, perform signal electromigration analysis sub-module 202 includes a produce transition matrix sub-module 212 which produces a state-analysis-based transition matrix using state analysis data from the logic circuit design, and a define transition submatrices sub-module 214 which defines transition submatrices by partitioning the state-analysis-based transition matrix for the logic circuit design. In one or more embodiments, the transition submatrices cover the entire transition matrix. In addition, the perform signal electromigration analysis sub-module 202 includes, in one or more embodiments, a determine per simulation weighting factors sub-module 216 which facilitates determining per simulation weighting factors for the signal electromigration analysis using the transition submatrices and switching factor data. In one or more embodiments, perform signal electromigration analysis sub-module 202 further includes a weight collected electrical current data sub-module 218, which applies the determined per simulation weighting factors to weight, for signal electromigration analysis, electrical current data collected from a plurality of timing situations of a transient simulator for the logic circuit design. In addition, perform signal electromigration analysis sub-module 202 includes an assess signal electromigration impact sub-module 220, which uses the weighted electrical current data in assessing signal electromigration impact on circuit performance of the logic circuit design.

As illustrated in FIG. 2C, in one or more embodiments, define transition submatrices sub-module 214 can include a define one transition submatrices type sub-module 222 to facilitate defining one type of transition submatrices from one partitioning of the state-analysis-based transition matrix, and a define another transition submatrices type sub-module 224 to facilitate defining another type of transition submatrices from another partitioning of the state-analysis-based transition matrix. In one or more embodiments, the per simulation weighting factors are determined using at least one submatrices type of the one transition submatrices type and the other transmission submatrices type. In one or more embodiments, the one transition submatrices type includes transition submatrices per output of the logic circuit design, and the other transition submatrices type includes transition submatrices per timing arc (or propagate segment (pseg)) of the logic circuit design.

In one or more implementations, determining the per simulation weighting factors for the electromigration analysis can further include ascertaining one set of per simulation weighting factors using the transition submatrices per output of the logic circuit design. Based on there being no zeroing of output switching factors associated with use of the transition submatrices per output, then the ascertained one set of weighting factors can be used as the determined per simulation weighting factors for the electromigration analysis.

In one or more implementations, determining the per simulation weighting factors for the electromigration analysis further include using both types of per simulation weighting factors. For instance, based on there being a zeroing of one or more output switching factors employing the transition submatrices per output, then determining of the per simulation weighting factors for electromigration analysis further includes ascertaining another set of per simulation weighting factors using the transition submatrices per timing arc of the logic circuit design. Based on there being no singularity associated with use of the transition submatrices per timing arc of the logic circuit design, then the ascertained other per simulation weight factors can be used as the determined per simulation factors for the signal electromigration analysis. In one or more embodiments, based on there being one or more singularities associated with the transition submatrices per timing arc of the logic circuit design, then the ascertained one set of per simulation weighting factors using the transition submatrices per output can be used as the determined per simulation weighting factors for the signal electromigration analysis.

In one or more embodiments, where the transition matrix is determined to include one or more multi-state transition simulations, then the per simulation weighting factors for the signal electromigration analysis can be determined using the full timing model SEM weight analysis, that is, using the state-analysis-based transition matrix rather than the transition submatrices.

In one or more implementations, using the weighted electrical current data in assessing signal electromigration impact occurs within a transistor-level static timing context.

Advantageously, one or more aspects disclosed herein improve processing within a computing environment by facilitating design and manufacture of integrated circuits, specifically, by facilitating very large-scale integration (VLSI) designs and devices based on analysis (and optimization) of circuit designs to resolve one or more identified signal electromigration issues. Disclosed herein, in one or more embodiments, is an enhanced design tool, or enhanced signal electromigration analysis and circuit design tool, to facilitate performing automated electromigration analysis and automated resolving, based on evaluating signal electromigration metrics for violations, a signal electromigration metric violation of the logic circuit design, and where required to initiate modification of a logic circuit design of an integrated circuit. The tool is particularly advantageous in analyzing high performance custom logic circuit designs. In one or more embodiments, the signal electromigration analysis and circuit design module and process disclosed improve the circuit design process by saving time in evaluating and resolving signal electromigration metric violations, as well as by reducing the number of simulations required of a logic circuit design of an integrated circuit. Advantageously, in one or more embodiments, the automated signal electromigration violation resolution processing disclosed also identifies resultant real signal electromigration violations of the circuit design by, in part, automatically resolving where possible any signal electromigration violations through auto-adjusting of, for instance, a switching factor of the logic circuit design, such as described herein.

In one or more embodiments, the signal electromigration analysis and circuit design module is used, in accordance with one or more aspects of the present disclosure, to perform signal electromigration analysis and circuit design processing. FIG. 3A depicts one example of a signal electromigration analysis and circuit design process 300, such as disclosed herein. The process is executed, in one or more embodiments, by a computer (e.g., computer 101 (FIG. 1)), and/or one or more processor sets, such as a processor or processing circuitry (e.g., of processor set 110 of FIG. 1). In one example, code or instructions implementing the process, are part of a module, such as signal electromigration analysis and circuit design module 200. In other examples, the code can be included in one or more other modules and/or one or more other sub-modules of one or more other modules. Various options are available.

As illustrated in FIG. 3A, in one example, signal electromigration analysis and circuit design process 300 executing on one or more computers (e.g., computer 101 of FIG. 1), one or more processor sets (e.g., processor set 110 of FIG. 1, such as a processor or processing circuitry of the processor set) performs signal electromigration analysis on a logical circuit design for an integrated circuit 302. One embodiment of performing signal electromigration analysis on a logic circuit design 302 is described further below with reference to FIG. 3B. Continuing with FIG. 3A, the signal electromigration analysis circuit design process 300 includes, in one or more embodiments, auto-resolving, based on evaluating the signal electromigration metrics for a violation, a signal electromigration metric violation of the logic circuit design 304. The automated resolving includes generating a signal electromigration limit-to-metric ratio for the signal electromigration metric violation of the logic circuit design 306, and auto-adjusting, using the generated signal electromigration limit-to-metric ratio, a switching factor of the logic circuit design to facilitate resolving the signal electromigration metric violation of the logic circuit design 308. Further, signal electromigration analysis and circuit design process 300 includes, in one or more embodiments, reevaluating the signal electromigration metrics of the logic circuit design using the auto-adjusted switching factor to confirm automated resolution of the signal electromigration metric violation 310.

FIG. 3B depicts one embodiment of performing signal electromigration analysis on a logic circuit design, which can be used in association with automated signal electromigration violation resolution processing such as described herein. As illustrated, performing signal electromigration analysis on a logical circuit design 302 includes, in one or more embodiments, producing a state-analysis-based transition matrix using state analysis data for the logic circuit design 312, and defining transition submatrices by partitioning the state-analysis-based transition matrix for the logic circuit design 314. Further, performing signal electromigration analysis on the logic circuit design includes, in one or more embodiments, determining per simulation weighting factors for the signal electromigration analysis using the transition submatrices and switching factor data 316, and applying the determined per simulation weighting factors to weight, for signal electromigration analysis, electrical current data collected from a plurality of timing situations of a transient simulator for the logic circuit design 318. In addition, performing signal electromigration analysis on the logic circuit design 302 includes, in one embodiment, using the weighted electrical current data in assessing signal electromigration impact on circuit performance on the logic circuit design 320.

In one or more embodiments, the signal electromigration analysis and circuit design process 300 can further include comparing, based on confirming the automated resolution of the signal electromigration metric violation, the auto-adjusted switching factor to a predefined minimum switching factor for the logic circuit design to confirm that the auto-adjusted switching factor is greater than or equal to the predefined lower switching factor limit. Should the auto-adjusted switching factor be below the predefined minimum switching factor for the logic circuit design, then a real signal electromigration metric violation is identified, and the process can further include initiating generating a modified circuit design based on identifying the real signal electromigration metric violation. For instance, generating the modified circuit design can include, by way of example, generating a modified logic circuit design to address one or more identified real signal electromigration issues or impacts on circuit performance based on the signal electromigration analysis of the logic circuit design. A variety of modifications to a logic circuit design can be, for instance, automatically implemented to address an identified signal electromigration issue. In one or more implementations, a logic circuit design can be modified automatically based on the signal electromigration analysis attempted auto-resolution to, for instance, prevent an electromigration issue by, for example: increasing a metal width to reduce current density; reducing frequency; lowering a supplied voltage; shortening a wire length; reducing buffer size and clock lines; etc.

Conventionally, in VLSI (very large-scale integration) digital design, fabricated devices can include millions of transistors implementing hundreds of storage devices, functional logic circuits, and the like. The designs are often segmented or partitioned into sub-blocks (such as cores, units, macros, subhierarchies, and the like) to make the design process more manageable. For example, the design, placement, and routing of circuits may be conducted at a high level and a sub-block level, where the high level considers the complete device including all sub-blocks (known as in-context design) and the sub-block level considers the design of a single sub-block (known as out-of-context design). While a sub-block level design can be used in multiple instances within a device, conventionally, only a single version of the design of the sub-block is produced.

Timing analysis and timing considerations for a sub-block conventionally include constraints, such as the specification of the arrival time (AT) for each input signal at the entry of the sub-block and the specification of the required arrival time (RAT) for generating each output signal of the sub-block. The required arrival time must consider the propagation delay through the circuit, including the slew rate of the output signal. The propagation delays, slew rates, and a like are influenced by a variety of factors to be analyzed in designing the integrated circuit. Signal electromigration (SEM) analysis, is one type of analysis of a logic circuit design to facilitate optimizing the circuit design.

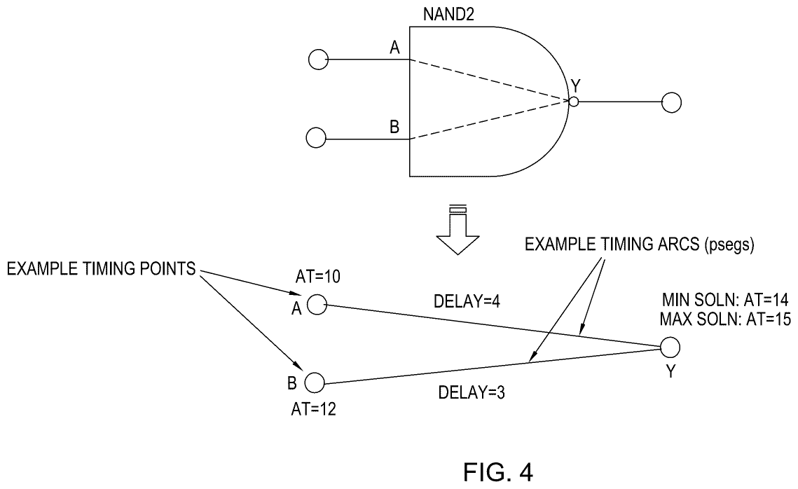

Electromigration is a type of potential fault mechanism in integrated circuits caused by the movement of atoms based on the flow of current through the material. Electromigration can result in both vacancies and deposits within, for instance, a wire, a gate, or other component of the integrated circuit. As part of the design and fabrication of integrated circuits, simulation of electromigration is performed in modern technology computer aided design (TCAD) tools. Results of the TCAD analysis can be used to modify, for instance, one or more design rules for a logic circuit design, and thereby modify the logic circuit design itself to further resist signal electromigration during operation of the fabricated integrated circuit. In accordance with one or more aspects, automated signal electromigration violation resolution processing is provided, which can be combined with automated signal electromigration analysis, such as described below with reference to FIGS. 4-13. Those skilled in the art will note, however, that the automated signal electromigration analysis processes described with reference to FIGS. 4-13 are provided by way of example only. Other automated signal electromigration analysis processes can be used in combination with an automated signal electromigration violation resolution process, such as disclosed and described further herein below with reference to FIG. 14. In one or more embodiments, where the automated signal electromigration violation resolution process identifies a real signal electromigration violation, the process can also include an initiating modification of one or more logic circuit designs to, for instance, eliminate an out-of-specification electromigration issue or otherwise reduce or minimize signal electromigration of the integrated circuit being fabricated.

### Automated Signal Electromigration Analysis

In one or more embodiments disclosed herein, certain novel static-transistor-level timing processes are employed to facilitate signal electromigration analysis. The processes disclosed allow for a highly automated set-up, with high performance relative to conventional dynamic signal electromigration processes, and provide excellent coverage since all possible charge states are considered.

In one or more embodiments, the signal electromigration analysis disclosed herein determines metrics to assess impact of signal electromigration on the resultant integrated circuit during the design phase. The metrics include, for instance, equivalent average DC current (I_{dc}), root mean square current (Iᵣₘₛ) and maximum current during a clock period (Iₚₑₐₖ). The determined metrics are compared to allowable limits to identify any anticipated signal electromigration violations. In one or more embodiments, weighting factors are determined to apply to the ascertained electrical current data, which as described herein, is collected from a plurality of timing simulations of a transient simulator (or timing simulator) for the logic circuit design (in one embodiment).

By way of example, FIG. 4 illustrates one embodiment of a logic gate and a related timing graph model for the logic gate. In this example, the logic gate is a NAND2 gate with inputs A, B and output Y. Static timing builds a timing graph containing timing points (gate inputs/outputs) and timing arcs (delay segments through the gates/wires, also referred to herein as propagate segments or psegs). In one or more embodiments, timing data is propagated through the timing graph, which can be used to determine if data signals arrive too early or too late relative to clocks, to satisfy constraints, that is, the appropriate data is to be latched in the appropriate clock cycle. The initial arrival times (ATs) are inserted at the primary inputs, and timing arc delays are determined. The determined arc delays include separate early and late, clock and data signals, side inputs, rise/fall, etc. Results are propagated to timing points, and cumulative effects of delays through the design are obtained. The clock signal AT is compared to the data signal AT at the latches to ensure proper capture of data by each latch. Note that although FIG. 4 illustrates one single gate, in practice, the logic circuits can be made up of hundreds to millions of logic gates.

Delays and/or slews are evaluated on the timing arcs, or propagate segments (psegs). The psegs each represent a delay path, that is, a path a signal takes which is not instantaneous. One goal of static timing analysis is to estimate the delay and/or slew along a timing arc for circuit timing purposes. The delays and/or slews are a function of many factors including, for instance, differing side input states, early/late mode, rise/fall transitions, signals with differing clock cycles or differing start times, etc. Multiple calculations are typically required for a given pseg over varying conditions to determine all required delay/slew data. In the timing graph model of FIG. 4, one timing arc (or pseg) is determined to have a delay of four, and the other a delay of 3, with the minimum solution and maximum solution arrival times at the output noted. As explained, this is a single gate example only with single delay per arc shown. In practice, there may be tens of delays per arc, hundreds to millions of such gates in a design where timing propagates gate-to-gate.

Transistor-level static timing analysis builds many such timing graphs. Each represents a set of propagate segments with some input/output commonality. In one or more embodiments, channel connected components (CCCs) analysis can be used in an evaluation state. In one embodiment, the inputs can be defined as the gates, and the outputs the drains (driving other gates or nets) and the delay arcs (that is, timing arcs or psegs) are defined in between the inputs and outputs. Note there can be an arbitrary number of inputs and outputs and/or an arbitrary number of psegs in a given channel connected component. In one or more embodiments, all timing and signal electromigration analysis can occur per channel connected component, which is roughly the equivalent of a gate-based analysis with delays and/or slews calculated and propagated through the channel connected components of the logic circuit design.

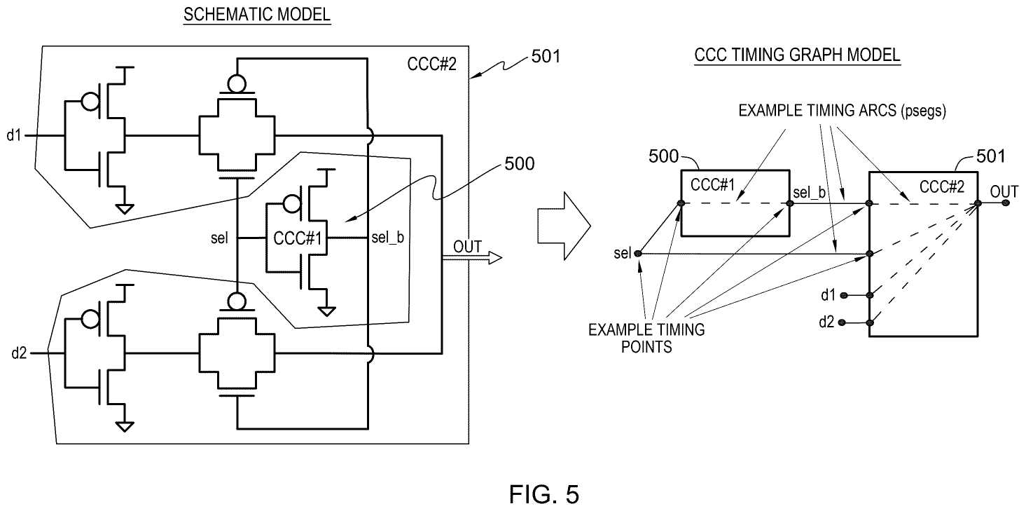

FIG. 5 illustrates one exemplary logic circuit or schematic model with two channel connected components CCC #1 500, CCC #2 501, which are shown in block format in the CCC timing graph model of FIG. 5. Inputs and outputs for each CCC block are illustrated, with the blocks being handled, in one or more embodiments, similar to the gates described above in generating the timing graph model. For each CCC, state-analysis occurs to determine (in one embodiment) all the delay evaluations required. State-analysis determines possible conditions a CCC may experience, and determines what are the feasible transitions for a given timing arc (or pseg) within the CCC.

Transistor level static timing analysis leverages transient simulation to evaluate timing. In particular, this is the method by which all delay calculations for a given timing arc are typically determined, that is, on all active timing arcs. State analysis determines the complete state for a given delay calculation, such as specific inputs/outputs of interest, early or late mode, rising or falling transition, specific clock cycle, specific side inputs, etc. For each timing arc (or pseg) there are many such entries, and each is a simulation row (or ‘simrow’). Each row defines the design state for a single simulation design state (transitions, side inputs, etc.). In one or more embodiments, there can be tens of these for a single timing arc, and thousands for all timing arcs of a CCC. The sim rows can each produce a different delay result on the timing arc. One simulation per delay and/or slew evaluation is obtained to cover all possible states. Standard static timing evaluates timing (delay/slew) per timing arc, then propagates the determined timings. A transition matrix can be defined from the state analysis data, and describes a subset of the total state data. Specifically, the transition matrix defines which pseg input is active and transitioning during a given delay/slew analysis, and it further defines the pseg output as active and transitioning or not, depending on the state of the circuit. In accordance with one or more aspects of disclosed herein, the transition matrix or state-analysis-based transition matrix, described is defined by such state analysis data.

In one or more embodiments disclosed herein, delays/slews can be modeled from voltage waveforms, and include current waveforms that are used herein to facilitate the signal electromigration analysis disclosed. Thus, transistor-level static timing analysis data is repurposed herein for signal electromigration analysis. In particular, certain data available for timing purposes can be reused or repurposed for signal electromigration analysis. For instance, the timing data can include or generate current waveforms and state analysis data such as described herein. In particular, note that the state analysis data is used herein for a completely different purpose than the standard timing applications.

Note also that many simulations occur per channel connected component. In accordance with one or more aspects, the per simulation charge data is to be merged. For instance, for each net, the charge data is summed for all simulations which impact that net. To do so, the weight for each simulation needs to be obtained. Note that the sum of all weights being applied must equal the net's switching factor. For instance, if the net switches at ten percent of the clock cycles, then the sum of the switching factor for that net is 0.1. If the net switches with each clock cycle, then the switching factor for that net is 1.0.

In accordance with one or more aspects of the present disclosure, a transition matrix is defined per channel connected component (e.g., per logic circuit design (e.g., per sub-circuit design)). The transition matrix indicates inputs and outputs of interest for a given simulation. In one embodiment, rows include input/output nets (and rise: fall (R: F) transitions), and columns indicate individual transient simulations (e.g., early/late mode, varying input transitions, varying side input states, varying timing arcs measured). A binary 1 equates to a transition of interest during simulation, otherwise the value is 0. Note in this regard that 0 does not mean no transition, but rather the transition is not of interest (e.g., not a measured pseg). In one or more embodiments, many more simulations than pins are ascertained, resulting in a highly under-determined matrix.

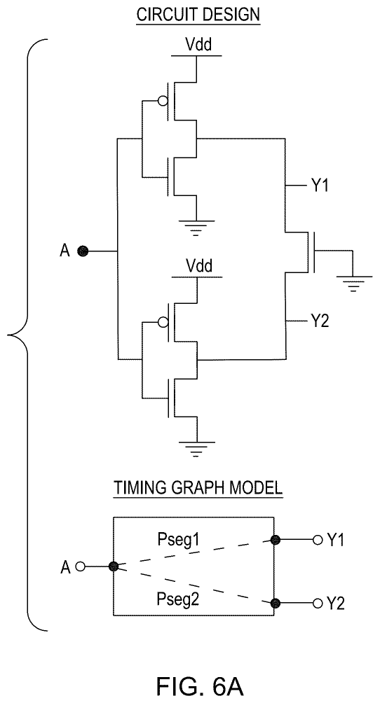

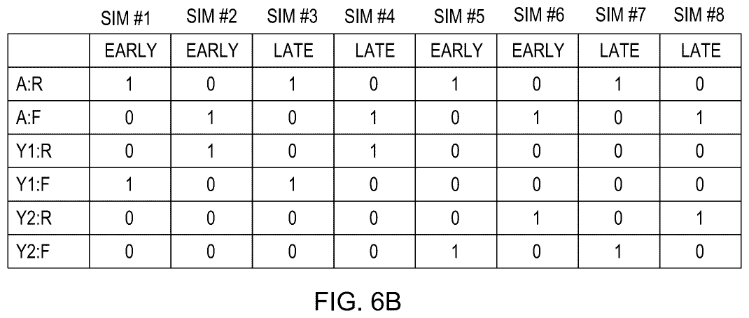

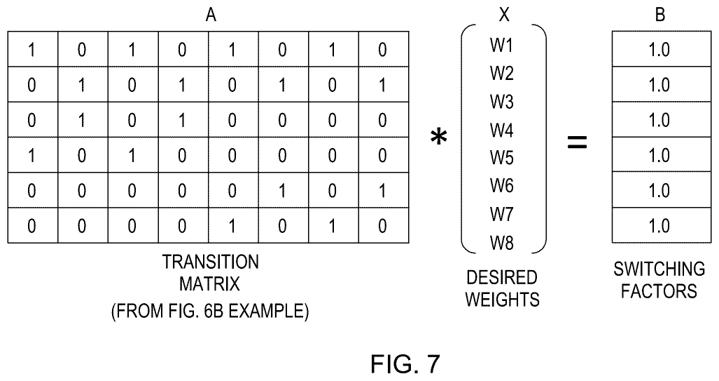

By way of example, FIG. 6A-6B illustrate one embodiment of a logic circuit design and associated timing graph model (FIG. 6A), and an exemplary state-analysis-based transition matrix (FIG. 6B). Note that the logic circuit design of FIG. 6A is one example only of a channel connected component for which signal electromigration analysis can be performed as described herein. As illustrated in the associated timing graph model of FIG. 6A, the channel connected component includes a single input A, and two outputs Y1, Y2, with two timing arcs or propagate segments (pseg1, pseg2) between the inputs and outputs.

FIG. 6B illustrates one embodiment of state analysis data (for a state-analysis-based transition matrix) containing transitions within, for instance, a channel connected component (CCC) expression of a logic circuit design, in accordance with one or more aspects of the present disclosure. Note that in the table, the 1 and 0 refer to changes or no changes of interest, and not states. Further, note that the table of FIG. 6B does not specify what physically switches, just what is of interest in a delay evaluation. In static timing, the calculations are performed per timing arc. For instance, in simulation #1 (sim #1), A pin rises and Y1 falls, which defines the delay calculation of interest (pseg1). Y2 also falls in simulation #1, but pseg2 is not in the delay arc of interest, so it is not marked in the table (or resultant transition matrix). In this manner, the state-analysis data, which defines every possible transition a channel connected component can make, can be leveraged to produce a state-analysis-based transition matrix for use in determining per-simulation signal electromigration weights, such as described herein. Note that the embodiment of FIG. 6B depicts one example only of state analysis data to form a transition matrix such as disclosed. In practice, there may be many more simulations for a given block or CCC.

As noted, in one or more embodiments of performing signal electromigration analysis of a logic circuit design such as described herein, per simulation weighting factors are to be determined. In one or more implementations, switching factors are assigned to each unique input/output net (e.g., logic circuit design). The switching factors represent a percentage of clock cycles that the net transitions. There are a variety of approaches to estimating fractions of a total switching factor value that can be used in determining the switching factors. In one or more embodiments, bounding switching factor values can be assigned (e.g., 0.1 static signals, 1.0 dynamic signals).

With the switching factors determined, per simulation weighting factors can then be ascertained. In one embodiment, weights can be determined using linear algebra on a transition matrix and switching factor vector, with the weight ‘W’ in the equivalent average DC current (I_{dc}) and root mean square current (Iᵣₘₛ) equations being the simulation weights. Note that the weighting factors are a function of the switching factors, and in the transition matrix. The weighting factors define contribution of a simulation's charge data to the cumulative I_{dc}, and Iᵣₘₛ. In particular, the sums of the weights in the non-zero columns must equal the switching factor, and the problem is under-determined, with more unknowns than equations.

FIG. 7 illustrates one embodiment representative of a signal electromigration weight evaluation solution. In this embodiment, linear algebra is used to solve for the weights or weighting factors: AX=B for X, where X is the unknown vector of weights (W1-W8). The weighting factor solution uses the transition matrix (A) and the switching factors vector (B), where the switching factor is a percent of clock cycles that the timing clock actually switches. The problem is an over constrained linear algebra problem, and many solution techniques are available, with one approach being the quadratic programing (or least squares) approach. In one embodiment, the approach includes:
Defining a target vector C (size=# columns of A, the same as X vector)
   Function of switching factors, non-zero transition matrix data
Seeking solution for vector X which minimizes error between itself and target, vector C
Defining QP: min (X−C)^{T}(X−C) such that AX=B (where T is transpose, and B is the switching factors)
This constrains X to one possible solution of AX=B
Representative solution: X=A^{T}(AA^{T})⁻¹(B−AC)+C

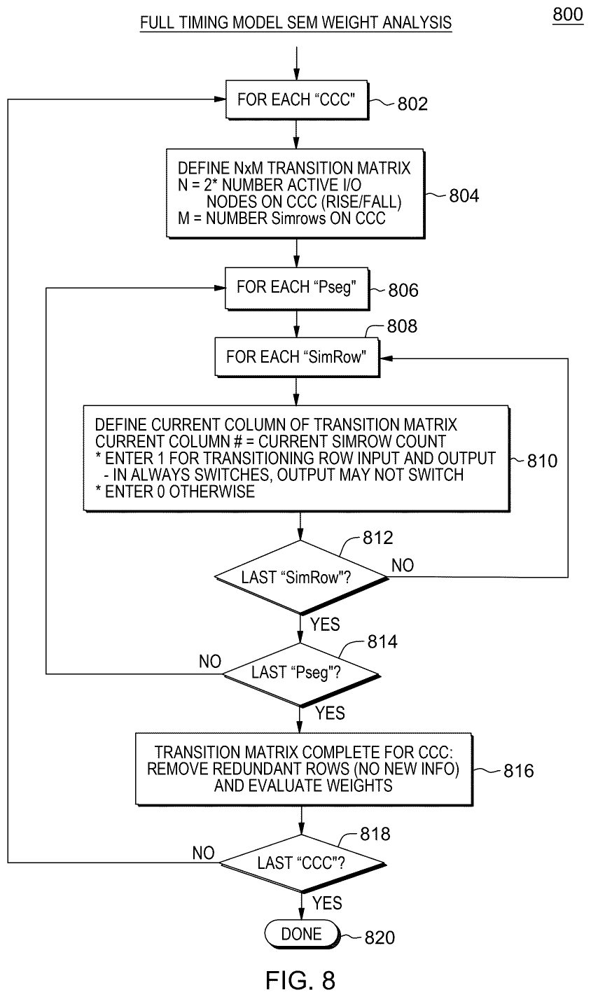

FIG. 8 depicts one embodiment of a full timing model signal electromigration (SEM) weight analysis workflow 800, in accordance with one or more aspects of present invention. In this SEM weight analysis process, a transition matrix is defined for each channel connected component (CCC) 802. In particular, for each CCC, an N×M transition matrix is defined 804 where (in one example only) N=2*number active I/O nodes on CCC (rise/fall) and M=number of simrows on the CCC. Note that in one embodiment, the data can be obtained in a prior loop over all CCC timing arcs (or psegs), counting nodes and simrows for that CCC, but they otherwise can be known from the state analysis, or other set-up or preprocessing. For each pseg (or timing arc) 806, and each simrow (or simulation row) 808, the process includes defining the current column of the transition matrix 810 by setting the current column number equal to the current simrow column, and entering a 1 for a transitioning row input and output (where input always switches, and output may not switch), or otherwise entering 0. Processing determines whether the last simrow has been processed 812, and if “No”, continues until each simrow for that pseg has been processed. The process continues for each pseg 814, and once the last pseg has been processed, the state-analysis-based transition matrix is complete for the CCC by, for instance, removing redundant rows (no new information), and then using the matrix in evaluating the weights 816 (in one or more embodiments). Processing continues for each channel connected component (CCC) 818, and completes once the last channel connected component (CCC) has been processed 820. Note that FIG. 8 depicts one embodiment only of a full timing model SEM weight analysis approach, such as described herein. In one or more other embodiments, it would be possible to, for instance, cache all state matrix information, and evaluate weights as a post process. The significant detail is that the state-analysis-based transition matrix is completely defined at that point.

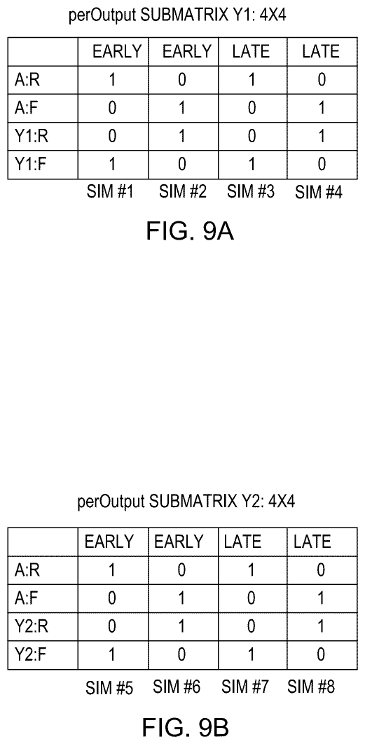

Note that in certain embodiments, the full timing model SEM weight analysis approach may not be optimal. For instance, matrices can in certain cases be singular, where no inverse exists, and no solution is possible. Further, the weighting data can in certain cases be poorly behaved. For instance, linear algebra can place constraints on the switching factors, which can be violated. When violated, negative weights can result, and these negative weights cannot be optimized. Further, overly small weights can require manual intervention to debug or scale up. Disclosed hereinbelow with reference to FIGS. 9A-13 are certain enhanced, automated signal electromigration analysis processes that mitigate these issues, and make the transistor level timing approach more practical for signal electromigration analysis and design modification.

One goal of the automated signal electromigration analysis and design modification approaches disclosed herein is to minimize singularities at all stages of the signal electromigration process. As noted a singular matrix indicates no solution is found for a channel connected component (CCC), and all weights for that channel connected component (CCC) are typically set to 0. A singularity can be driven by an imbalance in the switching factors out (SFₒᵤₜ) versus the switching factors in (SFᵢₙ) that violate matrix restraints.

An attribute of some transition matrices is that it can define switching inputs (e.g., for a NOR2 logic gate) where outputs may not switch. That is, not all input switching results in output switching (OS). When the output of a timing arc does not switch with the input, this condition is known as Non Output Switching (NOS). This is expected behavior and is not an issue, it is just an attribute of the matrix. What is an issue is when OS simulations have negative weights calculated and must be zeroed out. Pursuant to this disclosure, most/all negative weights are to be evaluated on NOS timing arcs. Advantageously, this allows the invalidative weights to be put on the arcs that contribute little charge.

In one or more implementations, the sum of the non-zero transient weights equals the nodal switching factor. In the under-constrained problem, an infinite number of solutions are possible. Some solutions require negative weights to satisfy the summation equation. Negative weights are undefined in the signal electromigration process and are artifacts of the matrix solution. One functional heuristic solution method is to zero out negative weights and resolve using the reduced matrix. This can produce a valid solution, but can also result in a singular matrix. Further, an issue can arise involving some positive weights being overly small, requiring further post processing to debug for validity, and/or scale-up for impact. This can be a time-consuming process and can result in an approximation. In one or more embodiments, negative weights can be excluded from the signal electromigration analysis, and small weights can under-count the impact. This can result in an optimistic solution, and addition manual intervention especially when zeroing “output switching” (OS) sensitizations, which can have significant charge associated. Further, the goal is to minimize zeroing of OS data by steering any zeroing to non-output switching (NOS) data.

As described herein, signal electromigration analysis processing is enhanced by defining transition submatrices through a partitioning of the state-analysis-based transition matrix for the logic circuit design. In one or more embodiments, the state-analysis-based data can be partitioned into multiple different types of transition submatrices including, for instance, perOutput and per timing arc (perPseg), as described herein.

FIGS. 9A-9B depict exemplary transition submatrices perOutput of a logic circuit design obtained by partitioning a full state-analysis-based transition matrix. In this example, the tables of FIGS. 9A and 9B are obtained by partitioning the full state-analysis data table of FIG. 6B, in one example only. In this process, the weight analysis defines and solves constraints using output-specific submatrices. In one embodiment, the defining of the transition submatrices is perOutput such that the submatrices span sensitizations for a single output, in which case the number of submatrices equals the number of outputs in the logic circuit design. The defined transition submatrices together span the full simulation space. In this case, the analysis is limited to only those inputs driving the particular output of the defined transition submatrix (including NOS). This results in few simulations, and larger weights to satisfy the switching factor. As noted, the approach in FIG. 8 can result in small weights, and the perOutput approach simplifies on the fly switching factor correction compared with using the full timing mode SEM weight analysis approach. Further, defining transition submatrices perOutput of the logic circuit design simplifies the solution and there are fewer differing switching factors in a given matrix. In this approach, each of the transition submatrices is solved independently for weights. Advantageously, using the per timing arc approach, singularities are substantially eliminated using default bounding switching factors.

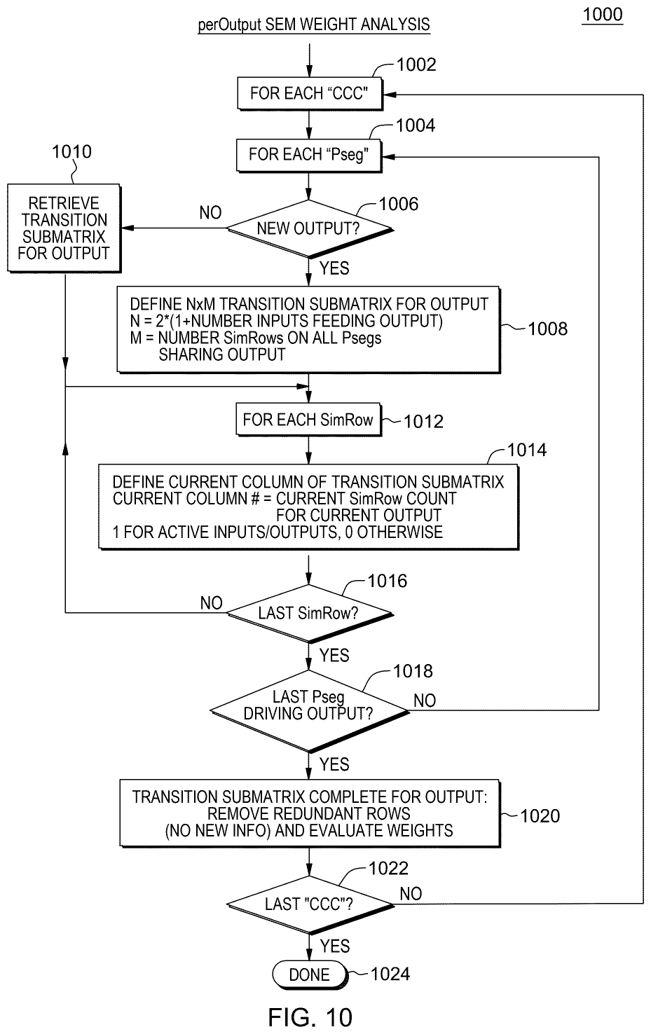

FIG. 10 illustrates one embodiment of a perOutput signal electromigration (SEM) weight analysis process 1000 which includes for each channel connected component (CCC) 1002, and for each pseg (or timing arc) 1004, determining whether this is a new output to be considered 1006. If the output is not new, then the transition submatrix for that output can be retrieved, for instance, from memory 1010. If the output is a new output to be considered, then a transition submatrix is defined for that output as an N×M transition submatrix, where N=2*(1+Number inputs feeding the output) and M=number of simrows on all psegs sharing the output.

For each simrow 1012 a current column of the transition submatrix is defined 1014, where the current column number equals the current simrow count for the current output, and where 1 is inserted for active inputs/outputs, and 0 otherwise. Processing determines whether the last simrow has been considered 1016, and if so, whether the last pseg driving the output has been considered 1018. If either is no, processing loops back until the last simrow has been processed, and the last pseg driving the output as been considered.

As illustrated in FIG. 10, the transition submatrix can be completed for that output 1020 by removing any redundant rows (that is, no new information), and then used to evaluate the weights 1020. Processing determines whether the last channel connected component (CCC) has been processed 1022, and repeats the process until complete 1024.

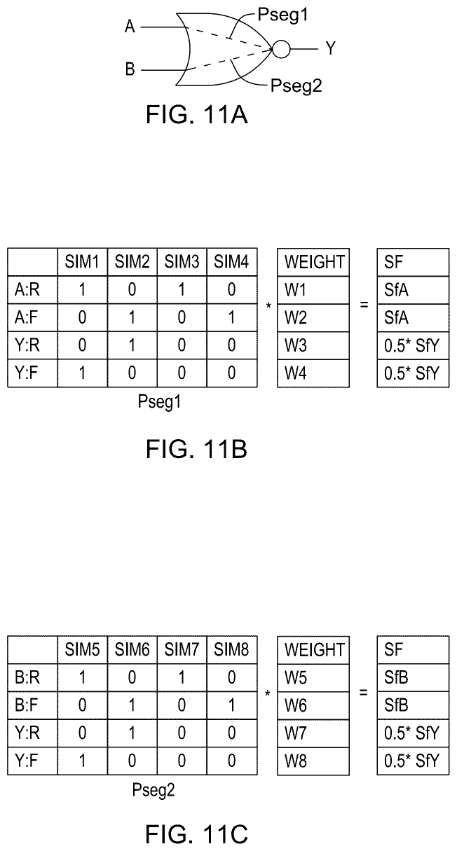

By way of further example, FIGS. 11A-11C illustrate another exemplary logic gate of a logic circuit design (FIG. 11A) and exemplary transition submatrices perPseg of the logic gate (FIGS. 11B-11C) obtained by partitioning the full state analysis transition matrix. In this approach, simulation weights are solved using pseg-specific submatrices. PerPseg means multiple submatrices are being defined, where each submatrix only spans sensitizations for a single input/output pair. In particular, the number of submatrices equals the number of psegs. The analysis is limited to one input and one output per submatrix. This advantageously eliminates extraneous and/or repeated contributions driving singularities, and negative OS weights. Also, as noted, the smaller submatrices are easier to manage when manual intervention is required. The perPseg approach is similar to the above described perOutput approach of FIGS. 9A-10, but with finer granularity in many cases. There are fewer sensitizations per matrix, which results in more robust weights to satisfy the switching factors than in the perOutput approach. Advantageously, using the perPseg approach, singularities are substantially eliminated using default bounding switching factors. Further, negative OS weights are further reduced, or eliminated, even relative to the perOutput approach. The exception is with templated CCCs, which can have multiple switching inputs/outputs, internal nets, or other items requiring the full timing model SEM weight analysis of FIG. 8.

In the example of FIGS. 11A-11C, the Pseg1 (FIG. 11B) and Pseg2 (FIG. 11C) depicted tables or transition submatrices can be obtained by partitioning the full state-analysis-based transition matrix for the logic circuit design of FIG. 11A. Note that in this regard that certain shared output switching factors (SF) need to be pro-rated, as illustrated in FIGS. 11B-11C. Because there are two psegs in this example, the switching factor is divided by 50%. That is, in the per Pseg approach the shared output switching factor can require scaling. With fan-in, output sensitizations are repeated over multiple inputs. A given pseg only considers some subset of the non-zero entries. But the sum of all weights over all non-zero entries needs to equal the total output switching factor. The solution is to scale the switching factor output based on its contributions to the total output weighting. For instance, the scaled switching factor output for a pseg is equal to the summation of the output switching psegs in a given submatrix (OS_{psegs}) divided by the summation of the output switching psegs in the entire CCC (OS_{ccc}).

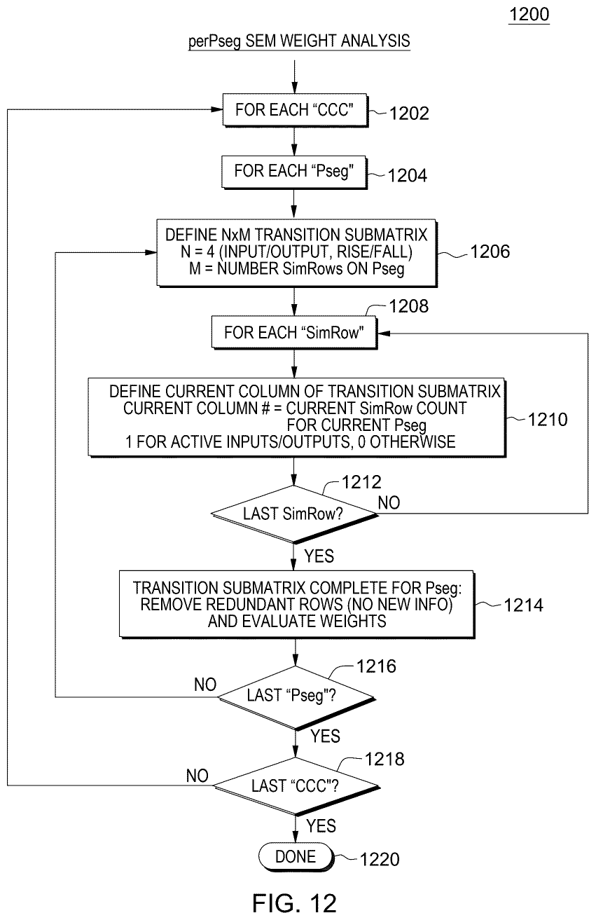

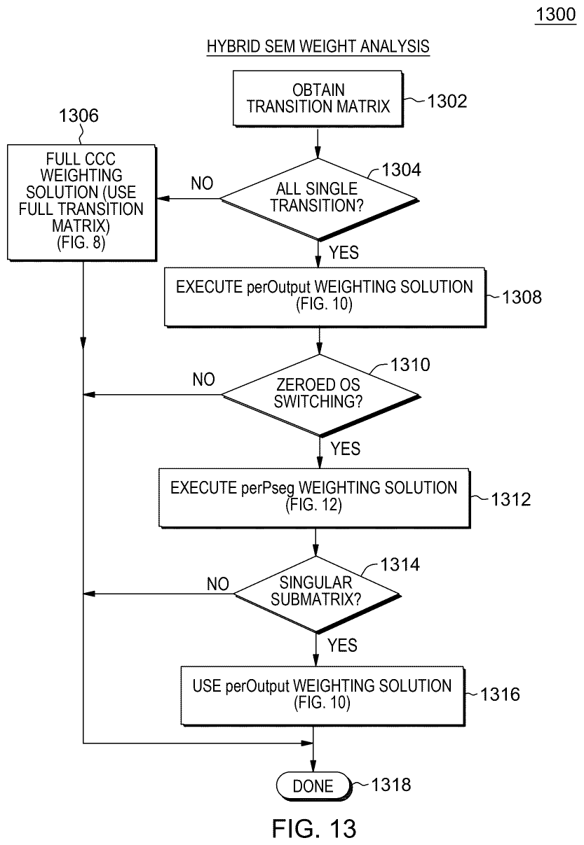

FIG. 12 illustrates one embodiment of a perPseg signal electromigration (SEM) weight analysis process 1200 which includes for each channel connected component (CCC) 1202, and for each pseg (or timing arc) 1204, defining an N×M transition submatrix, where N=4 (input/output, rise/fall) and M=number of simrows on the pseg 1206. For each simrow 1208, a current column of the transition submatrix is defined 1210, where the current column number equals the current simrow count for the current pseg, and where the 1 is inserted for active inputs/outputs, and 0 otherwise. Processing determines whether the last simrow has been considered 1212, and if not, processing loops back until the last simrow has been processed. As illustrated, the transition submatrix is completed for that pseg by removing any redundant rows (that is, no new information), and then evaluating the weights 1214. Processing determines whether the last pseg has been processed 1216, and if so, whether the last CCC has been considered 1218. If either is “No”, processing loops back until the last pseg has been processed for each CCC, which completes the process 1220.

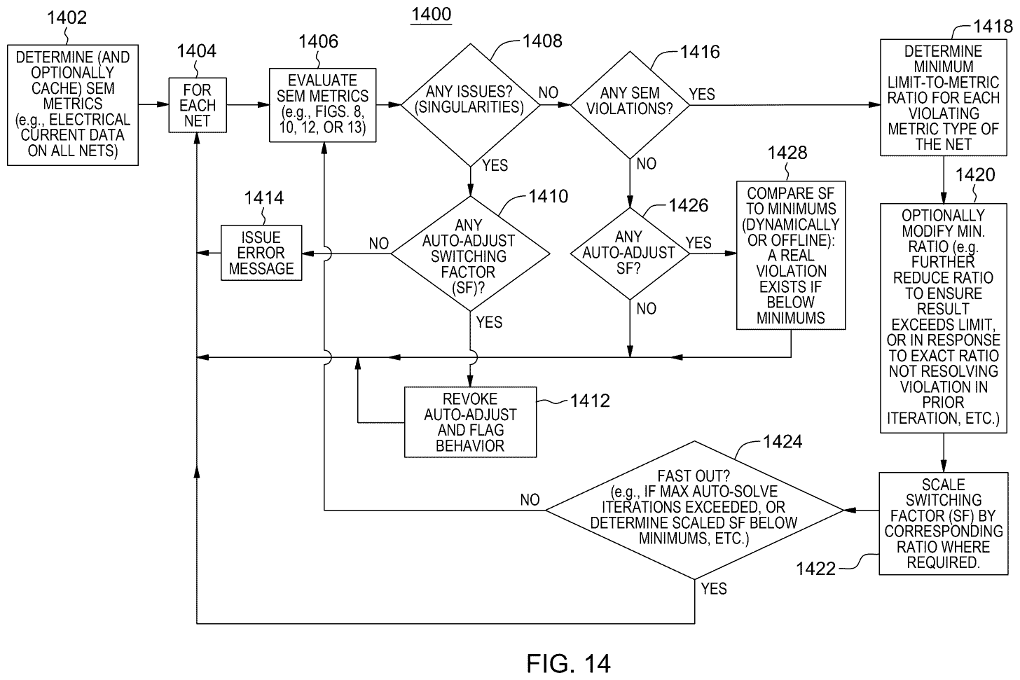

As noted herein, both the perOutput SEM weight analysis and perPseg SEM weight analysis processes have advantages and one or more issues associated therewith in comparison with the full timing model SEM weight analysis approach using the full transition matrix produced, as described herein, using state analysis data for a logic circuit design. For instance, the perPseg approach can drive singular submatrices in certain cases (e.g., less than 1% of all simulations). In cases of a fan-in, where the switching factor output (SFₒᵤₜ) is less than or equal to the summation of the switching factor input (SFᵢₙ), the perPseg approach can result in singularity. One solution is to use the perOutput approach under these conditions. Further, the perPseg approach can be more pessimistic than the perOutput approach, and another solution can be to use the perOutput approach when a result does not zero out OS data, and to fall back on the perPseg approach when the perOutput approach zeros OS data. In certain simulations, the full timing model (SEM) weight analysis approach may still be desirable. For instance, the perPseg approach requires a single input switching, and the perOutput approach requires single/shared input switching, and both approaches require single/no output switching. Rarely, certain specialized circuits violate these conditions. The logic circuit designs that violate the conditions are typically smaller circuits, not frequently used. In these cases, the full timing model (SEM) weight analysis can further be leveraged, such as described below with reference to the hybrid SEM weight analysis approach of FIG. 13.

As noted, in one or more embodiments, a hybrid SEM weight analysis approach can be used in determining per simulation weighting factors for signal electromigration analysis, such as described herein. Note that the approach of FIG. 13 represents one embodiment only of such a hybrid SEM weight analysis approach. The hybrid SEM weight analysis approach of FIG. 13 begins with obtaining (e.g., producing, retrieving, etc.) a state-analysis-based transition matrix for the logic circuit design 1302. The process determines whether the matrix contains all single transitions 1304. In one or more embodiments, single transitions include a 1 on an input node, and a 1 on an output node of the logic circuit design. As noted, for certain templates, there are sometimes multiple transitions occurring, and in those cases, the full channel connected component (CCC) weighting solution of FIG. 8 can be employed 1306 to determine the per simulation weighting factors for the signal electromigration analysis. Assuming that the transition matrix includes all single transitions, then processing can execute, in the embodiment of FIG. 13, the perOutput weighting solution of FIG. 10 1308. Processing then determines if there is any zeroed output switching data using the defined transition submatrices perOutput approach 1310, and if not, the process is complete 1318. If there is zeroed output switching executing the perOutput weighting solution, then (in one embodiment) processing executes the perPseg weighting solution of FIG. 12 1312. Processing determines whether this results in a singular submatrix 1314, and if “No” processing is complete 1318. Otherwise, if a singular submatrix is obtained using the perPseg weighting solution, then the hybrid SEM weight analysis approach of FIG. 13 reverts to using the perOutput weighting solution approach 1316 for determining the per simulation weighting factors for signal electromigration analysis.

Advantageously, using a hybrid SEM weight analysis approach, such as the hybrid SEM weight analysis approach of FIG. 13, singularities can be significantly reduced or eliminated, for instance, with either the perPseg or perOutput method. Any remaining singularities would typically be driven by templates, which can use the full timing model SEM weight analysis to resolve. In addition, output switching negative weights are significantly reduced by the perOutput approach, and largely eliminated by the perPseg approach.

Advantageously, computer-implemented methods, computer program products and computer systems are disclosed herein for facilitating signal electromigration analysis and circuit design by performing a plurality of signal transition current/charge density evaluations, and solving for required per transition weights using linear algebra processing of at least one of a plurality of submatrix solution approaches, such that the sum of the weights for active transitions on a given net equals the set switching factor (SF) for that net, and applying the weights in a summation of charge across all transitions influencing the current through a given net. In one or more embodiments, the solution executes using submatrices defined perOutput of a channel connected component (CCC), which minimizes singular solutions, and insures adequate weight magnitudes. In another embodiment, the solution executes using submatrices defined perPseg of the channel connected component (CCC), which advantageously minimizes singularities and negative weights, and ensures adequate weights. Note that with the perPseg approach, outputs shared between matrices are pro-rated such that the sum of weights across all matrices equal the global switching factor. Performing the weighting solution using a plurality of submatrix solution approaches can be optimal in many cases, for instance, to minimize pessimism in the result, and manage any perPseg singularities. In one or more embodiments, the signal electromigration analysis disclosed herein is a static transistor-level timing-based signal electromigration analysis. In general, the signal electromigration analysis disclosed can be based on a plurality of charge data, with each representing a single transition.

The computer-implemented methods, computer program products and computer systems disclosed herein provide a due means for performing signal electromigration analysis leveraging transistor level static timing, and allow for efficient and accurate SEM analysis with minimal operator interaction. The processes disclosed herein utilize timing-based simulations on a design circuitry, providing extremely accurate sign-off quality SEM results, while avoiding high levels of human interaction required by existing industry standard SEM analysis approaches.

### Automated Signal Electromigration Violation Resolution

As noted, in one or more aspects, described herein are various automated signal electromigration analysis processes. When given a fixed set of switching factors, the processes reliably solved for simulation weights. Multiple simulations are performed, with each determining or calculating electrical current data on a set of logic circuit designs or nets for an integrated circuit. This electric current data is scaled or weighted by the simulation weight and summed. The final summation constitutes the signal electromigration solution. In one or more embodiments, a signal electromigration violation exists where the solution exceeds a predetermined allowed limit for the design. Note, however, that automated or manual signal electromigration analysis processes could be employed in combination with auto-resolving signal electromigration violations such as described herein.

In one or more aspects, automated signal electromigration violation resolution is disclosed for use, for instance, in combination with an automated signal electromigration analysis process, which includes an automated identification of signal electromigration violations, such as described herein. The violation resolution processes disclosed herein reliably automate, in one or more embodiments, the adjustment of switching factors to automatically close one or more signal electromigration violations. The process is iteratively applied to the different logic circuit designs to automatically resolve violations, where possible. In one of more embodiments, the signal electromigration metrics (or electrical current data) from the simulations is advantageously cached and reused during the automated signal electromigration violation resolution process to avoid repeating the need for circuit simulations. This minimizes overhead of repeated design loading, state analysis, simulations, etc.

Conventionally, signal electromigration analysis violation resolution is a time consuming process typically requiring significant manual intervention to clear violations. A signal electromigration violation occurs when a measured signal electromigration metric (Metric_{SEM}) exceeds a signal electromigration limit (Limit_{SEM}).

The signal electromigration analysis and violation resolution process starts with a set of one or more bounding conditions. The bounding condition(s) is typically non-physical. While sometimes the bounding value does equal a physical maximum switching factor (e.g., it caps at 1.0, which equals the clock switching once per clock cycle), more typically it is greater than the maximum the design would ever physically switch. For instance, passing under bounding non-physical conditions, the design would pass under more relaxed actual conditions; for example, the physical max may be 0.008, but analysis can bound using 0.1. In one or more embodiments, the bounding conditions can relate to the maximum frequency a given logic circuit design could possibly switch. Logic circuit designs which do not violate the limits using worst case values pose no risk. This typically represents the vast majority of logic circuit designs of an integrated circuit, such as, for instance, 99% or more of the logic circuit designs. The designs that do not violate the bounding conditions can be ignored. Any logic circuit designs or nets that violate the conditions need to be analyzed, and have their switching factors reduced. This approach limits the detailed analysis to only the failing subset of logic circuit designs, and avoids having to perform detailed switching factor analysis on all the logic circuit designs in an integrated circuit. Advantageously, disclosed herein are automated signal electromigration violation resolution processes which resolve as many metric violations as possible, and which advantageously identify real signal electromigration metric violations that require further intervention, such as a reconfiguration of the logic circuit design.

More particularly, disclosed herein are computer-implemented methods, computer programs, and computer systems which facilitate circuit design processing within a computing environment by simulating, via at least one processor set, signal electromigration (SEM) for a logic circuit design of an integrated circuit, where the simulating generates signal electromigration metrics for the logic circuit design. Further, the method includes automatedly resolving, based on evaluating the signal electromigration metrics for violations, a signal electromigration metric violation of the logic circuit design. The automatedly resolving includes generating a signal electromigration limit-to-metric ratio for the signal electromigration metric violation of the logic circuit design, and auto-adjusting, using the generated signal electromigration limit-to-metric ratio, a switching factor of the logic circuit design to facilitate resolving the signal electromigration metric violation of the logic circuit design. Further, the method includes reevaluating the signal electromigration metrics of the logic circuit design using the auto-adjusted switching factor to confirm automated resolution of the electromigration metric violation.

In one or more embodiments, the signal electromigration metric violation includes one or more violating signal electromigration metric types, and generating the signal electromigration limit-to-metric ratio includes generating a signal electromigration limit-to-metric ratio for the one or more violating signal electromigration metric types of the logic circuit design.

In one more embodiments, a violating signal electromigration metric type of the one or more violating signal electromigration metric types includes a direct current (DC) violation, and a signal electromigration limit-to-metric ratio for the direct current violation is defined as a Limit_{SEM}/Metric_{SEM} ratio, where Limit_{SEM} is a predetermined signal electromigration limit for the logic circuit design and Metric_{SEM} is a respective signal electromigration metric for the logic circuit design of the generated signal electromigration metrics.

In one or more embodiments, a violating signal electromigration metric type of the one or more violating signal electromigration metric types includes a root mean square (RMS) current violation, and a signal electromigration limit-to-metric ratio for the root mean square current violation is defined as a (Limit_{SEM}/Metric_{SEM})² ratio, where Limit_{SEM} is a predetermined signal electromigration limit for the logic circuit design and Metric_{SEM} is a respective signal electromigration metric for the logic circuit design of the generated signal electromigration metrics.

In one or more embodiments, the method further includes selectively modifying the signal electromigration limit-to-metric ratio, prior to auto-adjusting the switching factor using the signal electromigration limit-to-metric ratio, to facilitate resolving the signal electromigration metric violation of the logic circuit design. For instance, in one or more embodiments the signal electromigration limit-to-metric ratio can optionally be modified to further reduce the ratio to ensure that the metric result exceeds the limit, or in response to a prior ratio not resolving the violation in a prior iteration, etc.

In one or more embodiments, the signal electromigration metric violation includes multiple violating signal electromigration metric types, and generating the signal electromigration limit-to-metric ratio includes generating a signal electromigration limit-to-metric ratio for each violating signal electromigration metric type, and determining a minimum signal electromigration limit-to-metric ratio from the generated signal electromigration limit-to-metric ratios for the multiple violating signal electromigration metric types. Further, the auto-scaling of the switching factor uses the minimum signal electromigration minimum-to-metric ratio for the multiple violating signal electromigration metric types for the logic circuit design.

In one or more embodiments, the method further includes comparing, based on confirming the automated resolution of the signal electromigration metric violation, the auto-adjusted switching factor to a predefined minimum switching factor for the logic circuit design to confirm that the auto-adjusted switching factor is greater than or equal to the predefined lower switching factor limit. Further, in one or more embodiments, the method includes automatically identifying a real signal electromigration metric violation where the auto-adjusted switching factor is below the predefined minimum switching factor for the logic circuit design. Based on identifying the real signal electromigration metric violation, the method can further include initiating generating a modified circuit design through modifying of the logic circuit design to address the real signal electromigration metric violation.

In one or more embodiments, the method further includes determining, based on reevaluating the signal electromigration metrics, that a matrix singularity has occurred, and based on determining occurrence of the matrix singularity, automatically revoking the auto-adjusted switching factor and initiating other corrective action to resolve the signal electromigration metric violation due to occurrence of the matrix singularity.

In one or more embodiments, the simulating includes performing, by the at least one processor set, signal electromigration simulation on multiple logic circuit designs of the integrated circuit, and wherein the computer-implemented method further includes iteratively repeating the automated resolving and reevaluating for each logic circuit design of the multiple logic circuit designs of the integrated circuit.

By way of example, FIG. 14 depicts one embodiment of an automated signal electromigration violation resolution process, in accordance with one or more aspects of present disclosure. The automated signal electromigration violation resolution process 1400 starts with determining signal electromigration metrics, such as electrical current data, on all logic circuit designs or nets of an integrated circuit layout 1402. One or more signal electromigration simulations on a logic circuit design can be performed to generate the signal electromigration (SEM) metrics for a particular design. In one or more embodiments, the determined SEM metrics are optionally cached at the start to minimize any need to re-execute the signal electromigration simulation of the logic circuit design to reobtain the metrics. In one or more embodiments, the automated SEM violation resolution process 1400 is an iterative process that evaluates each logic circuit design or net of the integrated circuit separately 1404. For each logic circuit design, the process includes evaluating the respective, cached SEM metrics 1406. As described herein, this can be an automated signal electromigration analysis process, such as one or more of the processes described above in connection with, for example, FIGS. 8, 10, 12 & 13. As noted, in one or more embodiments, the SEM metrics, or electrical current data, calculated from the simulations can be advantageously cached for reuse. All logic circuit designs or nets of the integrated circuit with SEM violations are noted as part of evaluating the SEM metrics 1406. In one or more embodiments, a violation exists where a determined SEM metric (Metric_{SEM}) exceeds a predetermined SEM limit (Limit_{SEM}).

In one or more embodiments, the automated SEM violation resolution process 1400 determines whether there are any issues with the SEM metrics 1408. For instance, in one or more embodiments, processing determines whether there are any singularities in the matrix, such as described above. If “yes”, then processing determines whether there has been an auto-adjustment to the switching factor 1410, such as described herein. If “no”, then a real SEM violation has been identified and an error message can be electronically signaled 1414 to initiate otherwise resolving the violation, for instance, using one or more existing approaches for such violations. Where the switching factor has been auto-adjusted 1410, then the auto-adjustment to the switching factor is revoked, and the behavior of the logic circuit design is flagged 1412 before a next logic circuit design or net is selected for analysis and automated SEM violation resolution.

Assuming that there are no issues with the SEM metrics for the particular logic circuit design, the process determines whether there are any SEM violations for the logic circuit design 1416. Assuming that there are one or more SEM violations for the logic circuit design, then the process determines a minimum limit-to-metric ratio for each violating metric type of the logic circuit design or net 1418. Note that multiple violations can exist since, in one or more embodiments, multiple resistors can be provided to measure current on a given logic circuit design or net. Also note that multiple types of violations can exist. For instance, direct current metrics and root mean square metrics are industry standard current metrics for evaluating signal electromigration of a logic circuit design. In one or more embodiments, for each violating metric type (e.g., direct current, RMS current, etc.), a ratio of the associated limit to the metric is determined. In one or more embodiments, where a violating signal electromigration metric type is a direct current (DC) violation, the signal electromigration limit-to-metric ratio for the direct current violation is defined as a Limit_{SEM}/Metrics_{SEM} ratio, where Limit_{SEM} is the predetermined signal electromigration limit for the logic circuit design or net, and Metric_{SEM} is the respective electromigration metric for the logic circuit design of the generated signal electromigration metrics. Where the violating signal electromigration metric type is a root mean square (RMS) current violation, the signal electromigration limit-to-metric ratio for the root mean square current violation is defined as a (Limit_{SEM}/Metric_{SEM})² ratio. In one or more embodiments, the minimum ratio is determined as a minimum ratio across all violating metrics on the logic circuit design or net.

As illustrated in FIG. 14, the minimum limit-to-metric ratio for the SEM violation can optionally be further modified 1420, if desired. For instance, the ratio can be further reduced by some value or percentage to ensure that the metric result will be sufficiently below the limit so as to provide some margin, or in response to an exact ratio not resolving the violation in a prior iteration, etc.

The process further includes scaling the switching factor by the corresponding minimum limit-to-metric ratio where required 1422, based on the signal electromigration violation. In one or more embodiments, the scaled switching factor is tagged as having been auto-scaled, for further reference as described herein.

In one or more embodiments, the process further includes determining whether the automated SEM violation resolution has a fast-out qualification 1424 to reevaluating the SEM metrics. For instance, if desired, a maximum auto-resolve number of iterations can be set, and when exceeded, processing discontinues evaluation of the current logic circuit design and selects a next net for evaluation. Alternatively, when it's determined that a scaled switching factor is below a minimum, then there can be a fast-out to a next logic circuit design. Comparing the scaled switching factor against the minimum switching factors for the logic circuit design can cither be manual or automated, depending on the process. Assuming that the iteration does not result in a fast-out indication, then the SEM metrics are reevaluated using the auto-adjusted switching factor for any violations. Assuming that there are no signal electromigration violations identified for the logic circuit design after auto-adjusting the switching factor, such as described herein, processing determines whether there are any auto-adjustments to the switching factor 1426. If “yes”, then the auto-adjusted switching factor is compared to the minimum set switching factors, either dynamically or offline manually, and a real violation is identified where the auto-adjusted switching factor is below the set minimums for the logic circuit design 1428. If a real violation exists, it can be otherwise addressed, such as described herein. Once the logic circuit design duration is complete, a next logic circuit design or net is selected for evaluation and automated SEM violation resolution processing.

Note that, in one or more embodiments, reevaluating SEM metrics can include reevaluating the SEM weights using the updated switching factors and the cached electrical current data (SEM metrics). If the next iteration completes without issue (e.g., without singularities), and the SEM violations are resolved, then a record is made of the auto-generated switching factor as it will need to be compared to the allowable limits, either manually or in code, as described. If the next run completes without issue (e.g., without one or more singularities), and SEM violations are not resolved, further scaling can occur. For instance, scaler/address can be applied to aid resolution. For example, further ratio reduction can be achieved by some scalar which decreases each iteration to help drive the resolution (e.g., 0.99→0.98→0.97→etc.). If the next run experience is an issue (e.g., a singularity), the auto-generate switching factors are revoked and the violation is tagged for deeper investigation, such as via manual resolution. The process terminates once all SEM violations for a logic circuit design or either resolved, or tagged as needing an intervention. Further, any SEM violations which require an auto-adjusted switching factor less than the minimum allowable value for the circuit design require a hardware modification to be initiated to resolve.

Note further that the order of electrical current processing is irrelevant to the automated signal electromigration violation resolution process disclosed. For each logic circuit designed or net, the electrical current data or SEM metrics are determined by simulation, and optionally cached for future reference to facilitate reevaluation of the SEM metrics for one or more of the logic circuit designs. Alternatively, the SEM metric evaluation can include repeating the full electrical analysis by recalculating electrical current data as part of the SEM reevaluation. The caching of the SEM metrics (i.e., the calculated or determined electrical current data) facilitates processing by reducing the amount of simulations required for the logic circuit design.

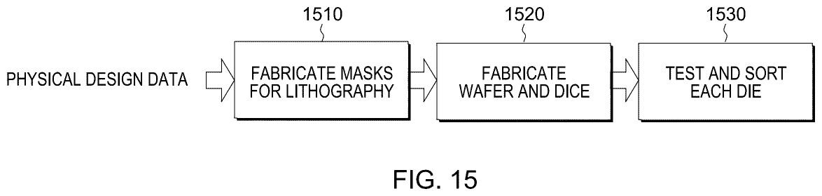

In one or more embodiments, a further step includes fabricating a physical integrated circuit in accordance with the validated VLSI circuit design. One non-limiting specific example that accomplishes this is described herein in connection with FIGS. 15-17. For example, a design structure, based on the VLSI design, is provided to fabrication equipment to facilitate fabrication of a physical integrated circuit in accordance with the design structure.

In one or more embodiments, a layout is prepared based on the analysis. In one or more embodiments, the layout is instantiated as a design structure. In one or more embodiments, a physical integrated circuit is fabricated in accordance with the design structure.

As noted, in one or more embodiments, the layout is instantiated as a design structure. A physical integrated circuit is then fabricated in accordance with the design structure. Refer also to discussion for FIGS. 15-17. FIG. 15 is a flow diagram of a design process used in semiconductor design, manufacture, and/or test. Once the physical design data is obtained, based, in part, on the design processes described herein, an integrated circuit designed in accordance therewith can be fabricated according to known processes that are generally described with reference to FIG. 15. Generally, a wafer with multiple copies of the final design is fabricated and cut (i.e., diced) such that each die is one copy of the integrated circuit. At block 1510, the processes include fabricating masks for lithography based on the finalized physical layout. At block 1520, fabricating the wafer includes using the masks to perform photolithography and etching. Once the wafer is diced, testing and sorting each die is performed at 1530 to filter out any faulty die. Furthermore, referring to FIGS. 15-17, in one or more embodiments, the at least one processor is operative to generate a design structure for the integrated circuit design in accordance with the VLSI design, and in at least some embodiments, the at least one processor is further operative to control integrated circuit manufacturing equipment to fabricate a physical integrated circuit in accordance with the design structure. Thus, the layout can be instantiated as a design structure, and the design structure can be provided to fabrication equipment to facilitate fabrication of a physical integrated circuit in accordance with the design structure. The physical integrated circuit will be improved (for example, because of proper signal electromigration mitigation) compared to circuits designed using prior art techniques, at least under conditions where there is the same CPU time budget for the design process. To achieve similar improvements with prior-art techniques, even if possible, would require expenditure of more CPU time as compared to embodiments of the invention.

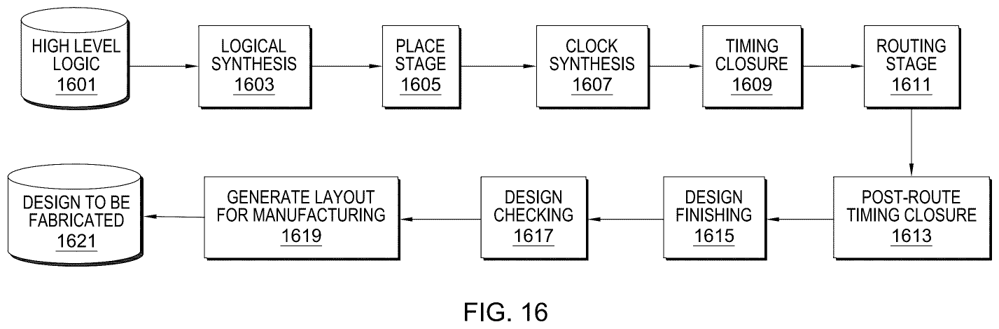

FIG. 16 depicts an example high-level Electronic Design Automation (EDA) tool flow, which is responsible for creating an optimized microprocessor (or other IC) design to be manufactured. A designer can start with a high-level logic description 1601 of the circuit (e.g. VHDL or Verilog). The logic synthesis tool 1603 compiles the logic and optimizes it without any sense of its physical representation, and with estimated timing information. Placement tool 1605 takes the logical description and places each component, looking to minimize congestion in each area of the design. The clock synthesis tool 1607 optimizes the clock tree network by cloning/balancing/buffering the latches or registers. The timing closure step 1609 performs a number of optimizations on the design, including buffering, wire tuning, and circuit repowering; its goal is to produce a design which is routable, without timing violations, and without excess power consumption. Routing stage 1611 takes the placed/optimized design and determines how to create wires to connect the components, without causing manufacturing violations. Post-route timing closure 1613 performs another set of optimizations to resolve any violations that are remaining after the routing. Design finishing 1615 then adds extra metal shapes to the netlist, to conform with manufacturing requirements. Checking steps 1617 analyze whether the design is violating any requirements such as manufacturing, timing, power, electromigration or noise. When the design is clean, the final step 1619 is to generate a layout for the design, representing all the shapes to be fabricated in the design to be fabricated 1621.

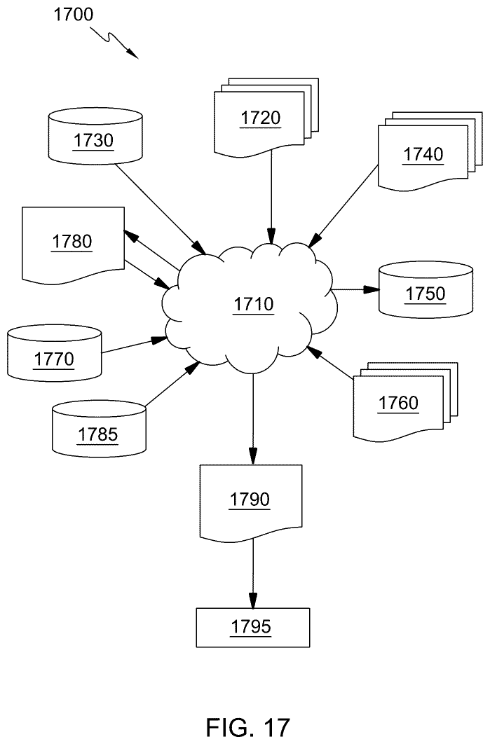

One or more embodiments integrate the timing and signal electromigration analysis techniques herein with semiconductor integrated circuit design simulation, test, layout, and/or manufacture. In this regard, FIG. 17 shows a block diagram of an exemplary design flow 1700 used for example, in semiconductor IC logic design, simulation, test, layout, and manufacture. Design flow 1700 includes processes, machines and/or mechanisms for processing design structures or devices to generate logically or otherwise functionally equivalent representations of design structures and/or devices, such as those that can be analyzed using timing analysis or the like. The design structures processed and/or generated by design flow 1700 may be encoded on machine-readable storage media to include data and/or instructions that when executed or otherwise processed on a data processing system generate a logically, structurally, mechanically, or otherwise function-ally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g., E-V writers), computers, or equipment for simulating design structures, any apparatus used in the manufacturing or test process, or any machines for programming functionality equivalent representations of the design structures into any medium (e.g., a machine for programming a programmable gate array).

Design flow 1700 may vary depending on the type of representation being designed. For example, a design flow 1700 for building an application specific IC (ASIC) may differ from a design flow 1700 for designing a standard component or from a design flow 1700 for instantiating the design into a programmable array, for example a programmable gate array (PGA) or a field programmable gate array (FPGA).

FIG. 17 illustrates multiple such design structures 1720 that is preferably processed by a design process 1710. Design structure 1720 may be a logical simulation design structure generated and processed by design process 1710 to product a logically equivalent functional representation of a hardware device. Design structure 1720 may also or alternatively comprise data and/or program instructions that when processed by design process 1710, generate a functional representation of the physical structure of a hardware device. Whether representing functional and/or structural design features, design structure 1720 may be generated using electronic computer-aided design (ECAD), such as implemented by a core developer/designer. When encoded on a gate array or storage medium, design structure 1720 may be accessed and processed by one or more hardware and/or software modules within design process 1710 to simulate or otherwise functionally represent an electronic component, circuit, electronic or logic module, apparatus, device, or system. As such, design structure 1720 may comprise files or other data structures including human and/or machine-readable source code, compiled structures, and computer executable code structure that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages, such as Verilog and VHDL, and/or higher level design languages, such as Cor C++.

Design process 1710 preferably employs and incorporates hardware and/or software modules for synthesizing, translating, or otherwise processing a design/simulation functional equivalent of components, circuits, devices, or logic structures to generate a Netlist 1780, which may contain design structures such as design structure 1720. Netlist 1780 may comprise, for example, compiled or otherwise processed data structures representing a list of wires, discrete components, logic gates, control circuits, I/O devices, modules, etc., that describes the connections to other elements and circuits in an integrated circuit design. Netlist 1780 may be recorded on a machine-readable data storage medium or programmed into a programmable gate array, a compact flash, or other flash memory. Additionally, or in the alternative, the medium may be a system or cache memory, buffer space, or other suitable memory.

Design process 1710 may include hardware and software modules for processing a variety of input data structure system, including Netlist 1780. Such data structure types may reside, for example, within library elements 1730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 1740, characterization data 1750, verification data 1760, design rules 1770, and test data files 1785, which may include input test patterns, output test results, and other testing information. Design process 1710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 1710 without deviating from the scope and spirit of the invention. Design process 1710 may also include modules for performing standard circuit design processes such as timing analysis, verification, design rule checking, place and route operations, etc. Improved placement can be performed as described herein.

Design process 1710 employs and incorporates logic and physical design tools such as HDL compilers and simulation model build tools to process design structure 1720 together with some or all of the depicted supporting data structures along with any additional mechanical design or data (if applicable), to generate a second design structure 1790. Design structure 1790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 1720, design structure 1790 preferably comprises one or 10 more files, data structures, or other computer-encoded data or instructions that reside on data storage media and that when processed by an ECAD system generate a logically or otherwise functionally equivalent form of one or more IC designs or the like. In one embodiment, design structure 1790 may comprise a compiled, executable HDL simulation model that functionally simulates the devices to be analyzed.

Design structure 1790 may also employ a data format used for the exchange of layout data of integrated circuits. and/or symbolic data format (e.g. information stored in a GDSII (GDS2), GLI, OASIS, map files, or any other suitable format for storing such design data structures). Design structure 1790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 1790 may then proceed to a stage 1795 where, for example, design structure 1790: proceeds to tape-out, is released to manufacturing, is released to a mask house, is sent to another design house, is sent back to the customer, etc.

The terminology used herein is for the purpose of describing particular embodiments only and is not intended to be limiting of the disclosure. As used herein, the singular forms “a”, “and” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A computer-implemented method of facilitating circuit design processing within a computing environment, the computer-implemented method comprising:
simulating, by at least one processor set, signal electromigration (SEM) for a logic circuit design of an integrated circuit, the simulating generating signal electromigration metrics for the logic circuit design;
automatedly resolving, based on evaluating the signal electromigration metrics for violations, a signal electromigration metric violation of the logic circuit design, the automatedly resolving comprising:
generating a signal electromigration limit-to-metric ratio for the signal electromigration metric violation of the logic circuit design; and
auto-adjusting, using the generated signal electromigration limit-to-metric ratio, a switching factor of the logic circuit design to facilitate resolving the signal electromigration metric violation of the logic circuit design; and
reevaluating the signal electromigration metrics of the logic circuit design using the auto-adjusted switching factor to confirm automated resolution of the signal electromigration metric violation.

2. The computer-implemented method of claim 1, wherein the signal electromigration metric violation comprises one or more violating signal electromigration metric types, and wherein generating the signal electromigration limit-to-metric ratio comprises generating a signal electromigration limit-to-metric ratio for the one or more violating signal electromigration metric types of the logic circuit design.

3. The computer-implemented method of claim 2, wherein a violating signal electromigration metric type of the one or more violating signal electromigration metric types comprises a direct current (DC) violation, and a signal electromigration limit-to-metric ratio for the direct current violation is defined as a Limit_{SEM}//Metric_{SEM} ratio, where Limit_{SEM} is a predetermined signal electromigration limit for the logic circuit design and Metric_{SEM} is a respective signal electromigration metric for the logic circuit design of the generated signal electromigration metrics.

4. The computer-implemented method of claim 2, wherein a violating signal electromigration metric type of the one or more violating signal electromigration metric types comprises a root mean square (RMS) current violation, and a signal electromigration limit-to-metric ratio for the root mean square current violation is defined as a (Limit_{SEM}/Metric_{SEM})² ratio, where Limit_{SEM} is a predetermined signal electromigration limit for the logic circuit design and Metric_{SEM} is a respective signal electromigration metric for the logic circuit design of the generated signal electromigration metrics.

5. The computer-implemented method of claim 2, further comprising selectively modifying the signal electromigration limit-to-metric ratio, prior to auto-adjusting the switching factor using the signal electromigration limit-to-metric ratio, to facilitate resolving the signal electromigration metric violation of the logic circuit design.

6. The computer-implemented method of claim 1, wherein the signal electromigration metric violation comprises multiple violating signal electromigration metric types, and wherein generating the signal electromigration limit-to-metric ratio comprises:
generating a signal electromigration limit-to-metric ratio for each violating signal electromigration metric type;
determining a minimum signal electromigration limit-to-metric ratio from the generated signal electromigration limit-to-metric ratios for the multiple violating signal electromigration metric types; and
wherein the auto-adjusting of the switching factor uses the minimum signal electromigration limit-to-metric ratio for the multiple violating signal electromigration metric types for the logic circuit design.

7. The computer-implemented method of claim 1, further comprising comparing, based on confirming the automated resolution of the signal electromigration metric violation, the auto-adjusted switching factor to a predefined minimum switching factor for the logic circuit design to confirm that the auto-adjusted switching factor is greater than or equal to the predefined lower switching factor limit.

8. The computer-implemented method of claim 7, further comprising automatically identifying a real signal electromigration metric violation where the auto-adjusted switching factor is below the predefined minimum switching factor for the logic circuit design, and based on identifying the real signal electromigration metric violation, initiating generating a modified circuit design through modifying of the logic circuit design based on identifying the real signal electromigration metric violation.

9. The computer-implemented method of claim 1, further comprising determining, based on reevaluating the signal electromigration metrics, that a matrix singularity has occurred, and based on determining occurrence of the matrix singularity, automatically revoking the auto-adjusted switching factor and initiating other corrective action to resolve the signal electromigration metric violation due to the occurrence of the matrix singularity.

10. The computer-implemented method of claim 1, wherein the simulating comprises performing, by the at least one processor set, signal electromigration simulation on multiple logic circuit designs of the integrated circuit, and wherein the computer-implemented method further comprises iteratively repeating the automatedly resolving and reevaluating for each logic circuit design of the multiple logic circuit designs of the integrated circuit.

11. A computer program product for facilitating circuit design processing within a computing environment, the computer program product comprising:
a set of one or more computer-readable storage media; and
program instructions, collectively store in the set of one or more storage media, for causing at least one processor set to perform computer operations comprising:
simulating, by at least one processor set, signal electromigration (SEM) for a logic circuit design of an integrated circuit, the simulating generating signal electromigration metrics for the logic circuit design;
automatedly resolving, based on evaluating the signal electromigration metrics for violations, a signal electromigration metric violation of the logic circuit design, the automatedly resolving comprising:
generating a signal electromigration limit-to-metric ratio for the signal electromigration metric violation of the logic circuit design; and
auto-adjusting, using the generated signal electromigration limit-to-metric ratio, a switching factor for the logic circuit design to facilitate resolving the signal electromigration metric violation of the logic circuit design; and
reevaluating the signal electromigration metrics of the logic circuit design using the auto-adjusted switching factor to confirm automated resolution of the signal electromigration metric violation.

12. The computer program product of claim 11, wherein the signal electromigration metric violation comprises one or more violating signal electromigration metric types, and wherein generating the signal electromigration limit-to-metric ratio comprises generating a signal electromigration limit-to-metric ratio for the one or more violating signal electromigration metric types of the logic circuit design.

13. The computer program product of claim 12, wherein a violating signal electromigration metric type of the one or more violating signal electromigration metric types comprises a direct current (DC) violation, and a signal electromigration limit-to-metric ratio for the direct current violation is defined as a Limit_{SEM}/Metric_{SEM} ratio, where Limit_{SEM} is a predetermined signal electromigration limit for the logic circuit design and Metric_{SEM} is a respective signal electromigration metric for the logic circuit design of the generated signal electromigration metrics.

14. The computer program product of claim 12, wherein a violating signal electromigration metric type of the one or more violating signal electromigration metric types comprises a root mean square (RMS) current violation, and a signal electromigration limit-to-metric ratio for the root mean square current violation is defined as a (Limit_{SEM}/Metric_{SEM})² ratio, SEM where Limit_{SEM} is a predetermined signal electromigration limit for the logic circuit design and Metric_{SEM} is a respective signal electromigration metric for the logic circuit design of the generated signal electromigration metrics.

15. The computer program product of claim 12, further comprising selectively modifying the signal electromigration limit-to-metric ratio, prior to auto-adjusting the switching factor using the signal electromigration limit-to-metric ratio, to facilitate resolving the signal electromigration metric violation of the logic circuit design.

16. The computer program product of claim 11, wherein the signal electromigration metric violation comprises multiple violating signal electromigration metric types, and wherein generating the signal electromigration limit-to-metric ratio comprises:
generating a signal electromigration limit-to-metric ratio for each violating signal electromigration metric type;
determining a minimum signal electromigration limit-to-metric ratio from the generated signal electromigration limit-to-metric ratios for the multiple violating signal electromigration metric types; and
wherein the auto-adjusting of the switching factor uses the minimum signal electromigration limit-to-metric ratio for the multiple violating signal electromigration metric types for the logic circuit design.

17. A computer system for facilitating circuit design processing within a computing environment, the computer system comprising:
at least one processor set;
a set of one or more computer-readable storage media; and
program instructions, collectively store in the set of one or more storage media, for causing at least one processor set to perform computer operations comprising:
simulating, by at least one processor set, signal electromigration (SEM) on a logic circuit design of an integrated circuit, the simulating generating signal electromigration metrics for the logic circuit design;
automatedly resolving, based on evaluating the signal electromigration metrics for violations, a signal electromigration metric violation of the logic circuit design, the automatedly resolving comprising:
generating a signal electromigration limit-to-metric ratio for the signal electromigration metric violation of the logic circuit design; and
auto-adjusting, using the generated signal electromigration limit-to-metric ratio, a switching factor for the logic circuit design to facilitate resolving the signal electromigration metric violation of the logic circuit design; and
reevaluating the signal electromigration metrics of the logic circuit design using the auto-adjusted switching factor to confirm automated resolution of the signal electromigration metric violation.

18. The computer system of claim 17, wherein the signal electromigration metric violation comprises one or more violating signal electromigration metric types, and wherein generating the signal electromigration limit-to-metric ratio comprises generating a signal electromigration limit-to-metric ratio for the one or more violating signal electromigration metric types of the logic circuit design.

19. The computer system of claim 18, further comprising selectively modifying the signal electromigration limit-to-metric ratio, prior to auto-adjusting the switching factor using the signal electromigration limit-to-metric ratio, to facilitate resolving the signal electromigration metric violation of the logic circuit design.

20. The computer system of claim 17, wherein the signal electromigration metric violation comprises multiple violating signal electromigration metric types, and wherein generating the signal electromigration limit-to-metric ratio comprises:
generating a signal electromigration limit-to-metric ratio for each violating signal electromigration metric type;
determining a minimum signal electromigration limit-to-metric ratio from the generated signal electromigration limit-to-metric ratios for the multiple violating signal electromigration metric types; and
wherein the auto-adjusting of the switching factor uses the minimum signal electromigration limit-to-metric ratio for the multiple violating signal electromigration metric types for the logic circuit design.
